(19) United States
(12) Patent Application Publication
(10) Pub. No.: US 2026/0362728 A1
(43) Pub. Date: Nov. 12, 2026

(54) SEMICONDUCTOR DEVICE

(71) Applicant: SAMSUNG ELECTRONICS CO., LTD., Suwon-si (KR)

(72) Inventors: Kyungbin Chun, Suwon-si (KR); SEOKHOON KIM, Suwon-si (KR); PANKWI PARK, Suwon-si (KR); RYONG HA, Suwon-si (KR)

(73) Assignee: SAMSUNG ELECTRONICS CO., LTD., Suwon-si (KR)

(21) Appl. No.: 19/465,558

(22) Filed: Jan. 30, 2026

(30) Foreign Application Priority Data
May 7, 2025 (KR) 10-2025-0059016

(51) Int. Cl. H10D 30/01; H10D 30/00; H10D 64/23

(52) U.S. Cl. CPC H10D 30/0198; H10D 30/501; H10D 64/254

(57) ABSTRACT

Provided is a semiconductor device including a base insulating layer including a first surface and a second surface opposing the first surface, a channel structure on the first surface, a gate structure on the channel structure, source/drain patterns connected to opposite sides of the channel structure, a lower wiring structure on the second surface, a lower contact electrode connecting the lower wiring structure and at least one of the source/drain patterns, and a contact structure between the lower contact electrode and the one of the source/drain patterns, the contact structure including a first material having a valence band maximum higher than a valence band maximum of silicon, wherein the contact structure includes a first contact pattern on a lower surface of the one of the source/drain patterns, and a second contact pattern between the first contact pattern and the lower contact electrode, and wherein a content of the first material in the second contact pattern is greater than a content of the first material in the first contact pattern.

### CROSS-REFERENCE TO RELATED APPLICATION

This application claims priority to Korean Patent Application No. 10-2025-0059016 filed with the Korean Intellectual Property Office on May 7, 2025, the disclosure of which is incorporated herein in its entirety by reference.

### BACKGROUND

### 1. Field

Embodiments of the present disclosure relate to a semiconductor device.

### 2. Description of Related Art

The semiconductor device is used in various electronic devices, including a storage device for storing data and a processor for performing data arithmetic processing. With the advancement of the electronics industry, various measures for improving various characteristics such as the integration degree, reliability, speed, and function of semiconductor devices are being researched. For example, a semiconductor device having a three-dimensional structure is being proposed in order to overcome the limitations resulting from the reduction in the size of the semiconductor device.

In recent years, research has been conducted in which a power delivery network for routing signals provided to a semiconductor device is positioned on the rear surface of the substrate, in order to improve routing congestion and to scale the size of the semiconductor device.

### SUMMARY

One or more embodiments provide a semiconductor device having improved reliability.

According to an aspect of one or more embodiments, there is provided a semiconductor device including a base insulating layer including a first surface and a second surface opposing the first surface of the base insulating layer, a channel structure on the first surface, a gate structure on the channel structure, source/drain patterns connected to opposite sides of the channel structure, a lower wiring structure on the second surface of the base insulating layer, a lower contact electrode connecting the lower wiring structure and at least one of the source/drain patterns, and a contact structure between the lower contact electrode and the one of the source/drain patterns, the contact structure including a first material having a valence band maximum higher than a valence band maximum of silicon, wherein the contact structure includes a first contact pattern on a lower surface of the one of the source/drain patterns, and a second contact pattern between the first contact pattern and the lower contact electrode, and wherein a content of the first material in the second contact pattern is greater than a content of the first material in the first contact pattern.

According to another aspect of one or more embodiments, there is provided a semiconductor device including a base insulating layer including a first surface and a second surface opposing the first surface, a channel structure on the first surface of the base insulating layer, a gate structure on the channel structure, source/drain patterns connected to opposite sides of the channel structure and including silicon germanium (SiGe), a lower wiring structure on the second surface of the base insulating layer, a lower contact electrode connecting the lower wiring structure and at least one of the source/drain patterns, and a contact structure between the lower contact electrode and the one of the source/drain patterns, the contact structure including silicon germanium (SiGe), wherein the contact structure includes a first contact pattern on a lower surface of the one of the source/drain patterns and a second contact pattern located between the first contact pattern and the lower contact electrode, wherein the first contact pattern and the second contact pattern respectively include a main region and a boundary region below the main region, and wherein a content of germanium (Ge) in the boundary region of the first contact pattern and a content of germanium (Ge) in the boundary region of the second contact pattern are greater than a content of germanium (Ge) in the main region of the first contact pattern and a content of germanium (Ge) in the main region of the second contact pattern.

According to still another aspect of one or more embodiments, there is provided a semiconductor device including a base insulating layer including a first surface and a second surface opposing the first surface, a channel structure on the first surface of the base insulating layer, a gate structure on the channel structure, a first source/drain pattern and a second source/drain pattern connected to opposite sides of the channel structure and including silicon germanium (SiGe), an upper wiring structure on the first source/drain pattern and the second source/drain pattern, an upper contact electrode in contact with an upper surface of the first source/drain pattern and connecting the upper wiring structure and the first source/drain pattern, a lower wiring structure on the second surface of the base insulating layer, a lower contact electrode connecting the lower wiring structure and the second source/drain pattern, a first contact pattern on a lower surface of the second source/drain pattern, an upper surface of the first contact pattern contacting the lower surface of the second source/drain pattern, a second contact pattern below the first contact pattern, a third contact pattern located between the second contact pattern and the lower contact electrode, a lower surface of the third contact pattern contacting an upper surface of the lower contact electrode, wherein the first contact pattern, the second contact pattern, and the third contact pattern each include silicon germanium (SiGe), wherein the first contact pattern, the second contact pattern, and the third contact pattern each include a main region and a boundary region below the main region, and wherein a content of germanium (Ge) in the third contact pattern is greater than a content of germanium (Ge) in the second contact pattern, and a content of germanium (Ge) in the second contact pattern is greater than a content of germanium (Ge) in the first contact pattern.

According to further still another aspect of one or more embodiments, there is provided a method of manufacturing a semiconductor device including forming a base insulating layer including a first surface and a second surface opposing the first surface, forming a channel structure on the first surface of the base insulating layer, forming a gate structure on the channel structure, forming source/drain patterns connected to opposite sides of the channel structure, forming a lower wiring structure on the second surface of the base insulating layer, forming a lower contact electrode connecting the lower wiring structure and at least one of the source/drain patterns, and forming a contact structure between the lower contact electrode and the one of the source/drain patterns, the contact structure including a first material having a valence band maximum higher than a valence band maximum of silicon.

The forming of the contact structure includes forming a first contact pattern on a lower surface of the one of the source/drain patterns, and forming a second contact pattern between the first contact pattern and the lower contact electrode, wherein a content of the first material in the second contact pattern is greater than a content of the first material in the first contact pattern.

### BRIEF DESCRIPTION OF DRAWINGS

Embodiments will be more clearly understood from the following detailed description taken in conjunction with the accompanying drawings in which:

FIG. 1 is a plan view illustrating a semiconductor device according to one or more embodiments;

FIG. 2 is a cross-sectional view of the semiconductor device taken along line I1-I1′ of FIG. 1;

FIG. 3 is a cross-sectional view of the semiconductor device taken along line I2-I2′ of FIG. 1;

FIG. 4 is a cross-sectional view of the semiconductor device taken along the line I3-I3′ of FIG. 1;

FIG. 5 is an enlarged cross-sectional view of region A of FIG. 1;

FIG. 6 is a diagram for describing the content of germanium (Ge) included in the contact patterns;

FIGS. 7, 8, and 9 are drawings for describing the semiconductor device according to one or more embodiments;

FIGS. 10, 11, 12, 13, 14, 15, 16, 17, 18, 19, 20, 21, 22, 23, 24, 25, 26, 27, 28. 29, 30, 31, 32, 33, 34, 35, 36, 37, 38, 39, 40, 41, 42, and 43 are process cross-sectional views for illustrating a method of manufacturing a semiconductor device according to one or more embodiments.

### DETAILED DESCRIPTION

Hereinafter, various embodiments of the present disclosure will be described in detail with reference to the accompanying drawings so that those of ordinary skill in the art to which the present disclosure pertains may readily carry out the disclosure. The present disclosure may be implemented in various different forms and is not limited to the embodiments described herein.

In order to clearly describe the present disclosure, portions unrelated to the description have been omitted, and the same reference numerals are assigned to identical or similar elements throughout the entire specification.

In addition, the sizes and thicknesses of each component shown in the drawings are illustrated arbitrarily for convenience of explanation, and thus the present disclosure is not necessarily limited to what is depicted. For clarity of illustration of the various layers and regions in the drawings, the thicknesses are shown in an enlarged manner. In the drawings, for convenience of explanation, the thickness of some layers and regions is illustrated in an exaggerated manner.

In addition, when a portion such as a layer, film, region, or plate is described as being on or above another portion, this includes not only the case where it is immediately on the other portion, but also the case where another portion is interposed therebetween. Conversely, when a portion is said to be immediately on another portion, it means that there is no other portion interposed therebetween. In addition, stating that it is “on” or “above” a reference portion means that it is positioned on or below the reference portion, and does not necessarily mean that it is positioned “on” or “above” in the direction opposite to gravity.

In addition, throughout the specification, when any portion is described as including any component, this means that, unless specifically stated otherwise, other components are not excluded but may further be included.

In addition, throughout the specification, “in a plan view” refers to a case where the relevant portion is viewed from above, and “in a cross-sectional view” refers to a case where the relevant portion is viewed from the side when a cross section of the relevant portion is taken vertically.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. Also, the term “and/or” includes any and all combinations of one or more of the associated listed items. For example, an expression, “a and/or b” should be understood as including only a, only b and both a and b.

In the drawings relating to a semiconductor device according to one or more embodiments, by way of example, a Gate All Around (GAA), or Multi-Bridge Channel Field Effect Transistor (MBCFET™) including a nanowire or nanosheet is illustrated, but is not limited thereto. According to one or more embodiments, the semiconductor device may include a FinFET including a channel structure having a fin-shaped pattern, a tunneling FET, a 3D Stack Field Effect Transistor (3D-SFET) structure, and a Complementary Field Effect Transistor (CFET) structure.

Hereinafter, a semiconductor device according to one or more embodiments will be described with reference to the drawings.

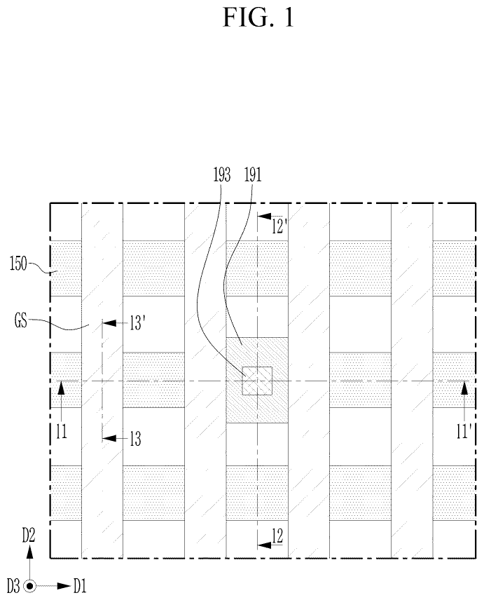

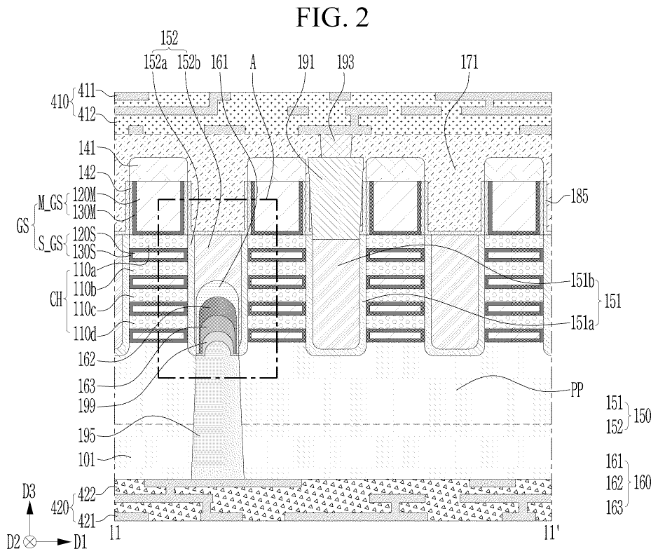

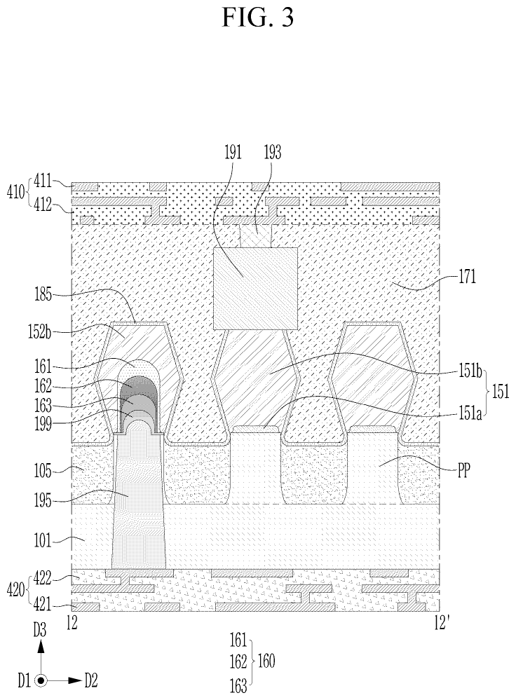

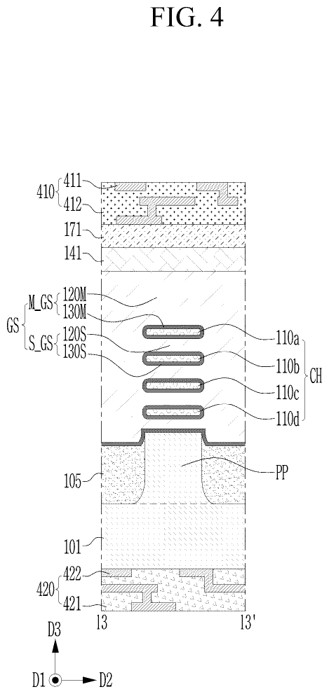

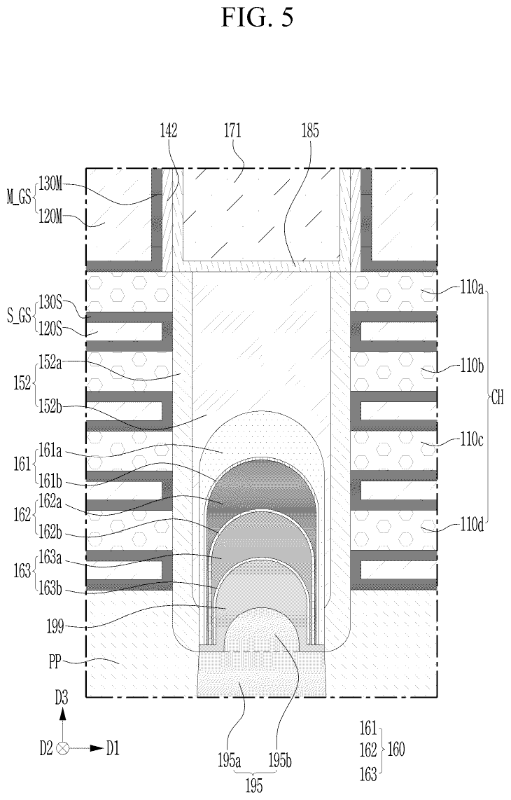

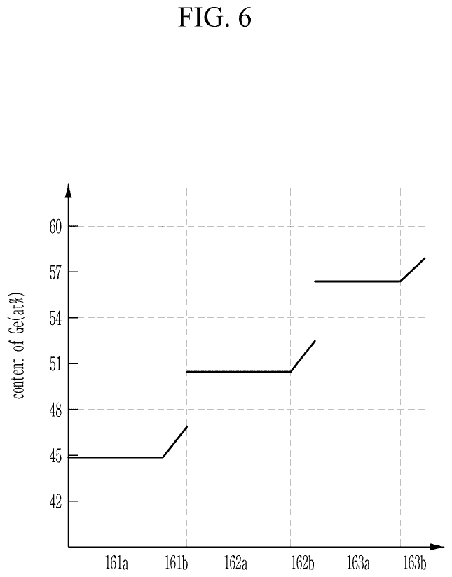

FIG. 1 is a plan view illustrating a semiconductor device according to one or more embodiments, FIG. 2 is a cross-sectional view of the semiconductor device taken along line I1-I1′ of FIG. 1, FIG. 3 is a cross-sectional view of the semiconductor device taken along line I2-I2′ of FIG. 1, FIG. 4 is a cross-sectional view of the semiconductor device taken along line I3-I3′ of FIG. 1, and FIG. 5 is an enlarged cross-sectional view of the A region of FIG. 1. FIG. 6 is a drawing for explaining the content of germanium (Ge) included in the contact patterns 161, 162, and 163.

Referring to FIG. 1 to FIG. 5, a semiconductor device according to one or more embodiments may include a base insulating layer 101 including a first surface and a second surface opposite to the first surface, a channel structure CH positioned on the first surface of the base insulating layer 101, a gate structure GS surrounding and adjacent to the channel structure CH, source/drain patterns 150 connected to opposite sides of the channel structure CH, a lower wiring structure 420 positioned on the second surface of the base insulating layer 101, a lower contact electrode 195 connecting the lower wiring structure 420 and the source/drain patterns 150, and a contact structure 160 positioned between the lower contact electrode 195 and the source/drain patterns 150.

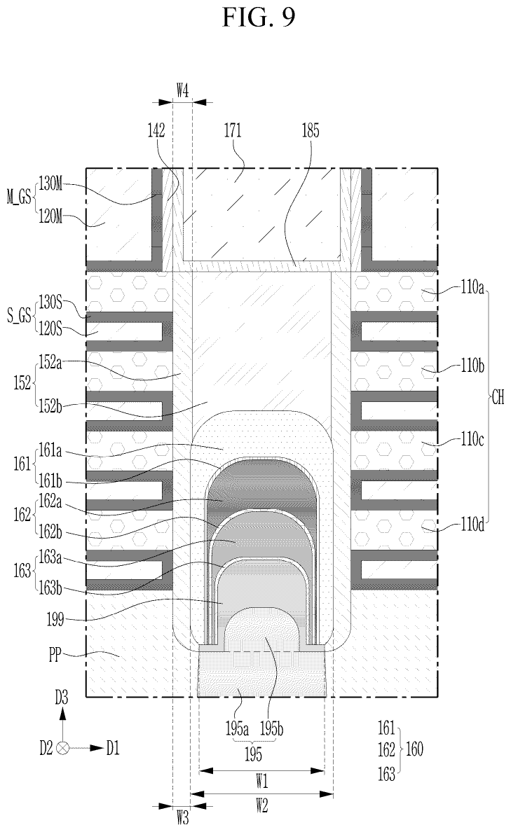

The base insulating layer 101 may be an insulating substrate. The base insulating layer 101 may include, for example, an oxide, a nitride, an oxynitride, or a combination thereof. For example, the base insulating layer 101 may include silicon oxide (SiO₂). The base insulating layer 101 is illustrated as a single layer, but embodiments are not limited thereto, and the base insulating layer 101 may include multiple layers. The base insulating layer 101 may be formed by filling an etched portion with an insulating material after the substrate 10 (see FIG. 9), which will be described later, is etched.

The first surface and the second surface of the base insulating layer 101 may be formed as planes parallel to the first direction D1 and the second direction D2 intersecting the first direction D1. For example, a first surface of the base insulating layer 101 may be an upper surface of the base insulating layer 101, and a second surface may be a lower surface of the base insulating layer 101. The upper surface of the base insulating layer 101 may be a surface opposite to the lower surface of the base insulating layer 101 in the third direction D3. The third direction D3 may be a direction perpendicular to the first direction D1 and the second direction D2. The lower surface of the base insulating layer 101 may be referred to as the rear surface (back side) of the base insulating layer 101. In some embodiments, a logic circuit of a cell region may be implemented on an upper surface of a base insulating layer 101.

A semiconductor device according to an example may further include protruding patterns PP positioned on the base insulating layer 101. The protruding patterns PP may be portions protruded in the third direction D3 from a first surface of the base insulating layer 101. The protruding patterns PP may be formed by filling the etched portions with an insulating material after the lower pattern BP, see FIG. 9 described below is etched.

The protruding patterns PP may extend in a first direction D1. The protruding patterns PP may be arranged spaced apart from each other in the second direction D2 on the first surface of the base insulating layer 101. Source/drain patterns 150 to be described below may be positioned on protruding patterns PP. The source/drain patterns 150 may be arranged spaced apart in the first direction D1 on each protruding pattern PP.

The protruding patterns PP may include an insulating material. The protruding patterns PP may include, for example, silicon oxide (SiO₂), silicon nitride (SiN_{X}), silicon oxynitride (SiON), or a combination thereof. In the example, the protruding patterns PP may include the same material as the base insulating layer 101. In the example, the protruding pattern PP and the base insulating layer 101 may be integrally formed. In this case, the boundary between the protruding pattern PP and the base insulating layer 101 may not be visually recognized.

The channel structures CH may be positioned on a first surface of the base insulating layer 101. As shown in FIGS. 2 and 3, when a protruding pattern PP is positioned on the base insulating layer 101, channel structures CH may be positioned on the protruding pattern PP. In the example, the channel structures CH may be arranged spaced apart from each other along the second direction D2 on the protruding pattern PP.

Referring to FIGS. 1 and 2, the channel structures CH may be arranged spaced apart from each other in the first direction D1 on the base insulating layer 101 and/or the protruding pattern PP. A plurality of channel structures CH positioned on one protruding pattern PP may be arranged spaced apart in a first direction D1. Each of the channel structures CH may include a first channel pattern 110a, a second channel pattern 110b, a third channel pattern 110c, and a fourth channel pattern 110d. A plurality of channel patterns 110a, 110b, 110c, 110d may be arranged spaced apart from each other in a third direction D3. In one embodiment, each of the plurality of channel patterns 110a, 110b, 110c, 110d may have a sheet shape. Each of the channel patterns 110a, 110b, 110c, 110d may be a nanosheet having a thickness of several nanometers in the third direction D3.

The channel structure CHs may provide a path through which current flows between the source/drain pattern 150s, which will be described below. Referring to FIGS. 2 and 4, the channel structures CH are disposed between the source/drain patterns 150, and may connect between the source/drain patterns 150. The channel structures CH may penetrate a portion of the gate structure GS in a direction intersecting the direction in which the gate structure GS, described below, extends (for example, the first direction D1). In FIGS. 2 and 4, the channel structures CH are shown such that four channel patterns 110a, 110b, 110c, 110d are arranged spaced apart in the third direction D3, but are not limited thereto, and the number of stacked channel patterns 110a, 110b, 110c, 110d included in one channel structure CH may be variously changed.

The channel structures CH may include a semiconductor material. For example, the channel structures CH may include group IV semiconductors such as silicon (Si) and germanium (Ge), group III-V compound semiconductors, and group II-VI compound semiconductors. In the embodiment, a protruding pattern PP may be positioned below the channel structure CH. Specifically, the protruding pattern PP may be positioned between the lowermost sub-gate structure S_GS among the plurality of sub-gate structures S_GS described below and the base insulating layer 101. The upper surface of the protruding pattern PP may contact the lower surface of the sub-gate structure S_GS positioned at the lowest portion among the plurality of sub-gate structures S_GS.

In one or more other embodiments, unlike that shown in FIGS. 2 to 4, the semiconductor device may not include the protruding pattern PP. In this case, a lower surface of the sub-gate structure S_GS positioned at a lowermost portion among the sub-gate structures S_GS may be in direct contact with the base insulating layer 101.

The semiconductor device according to one or more embodiments may further include a field insulating layer 105 positioned on the base insulating layer 101. The field insulating layer 105 may be positioned between two protruding patterns PP adjacent to each other in the second direction D2. The field insulating layer 105 may not be positioned on the upper surface of the protruding pattern PP.

The field insulating layer 105 may be positioned on the upper surface of the base insulating layer 101 and on side portions of the protruding patterns PP. The field insulating layer 105 may cover and/or be provided on the side surfaces of the protruding pattern PP entirely. As another example, the field insulating layer 105 may cover and/or be provided on a portion of the side surfaces of the protruding pattern PP. In such a case, a portion of the protruding pattern PP may protrude further in the third direction D3 than the upper surface of the field insulating layer 105.

The field insulating layer 105 may include, for example, an oxide, a nitride, an oxynitride, or a combination layer thereof. The field insulating layer 105 is illustrated as a single layer. However, embodiments are not limited thereto.

The gate structure GS may be positioned on the base insulating layer 101. A protruding pattern PP or a field insulating layer 105 may be positioned between the gate structure GS and the base insulating layer 101. The gate structure GS may extend on the base insulating layer 101 in a direction different from the direction in which the protruding pattern PP extends. For example, the gate structure GS may be extended on the base insulating layer 101 in a direction intersecting with the direction in which the protruding pattern PP extends for example, the second direction D2. The gate structure GS may be positioned on the base insulating layer 101. The gate structures GS may be arranged spaced apart from each other in the first direction D1. The gate structure GS may include the sub-gate structure S_GS and the main gate structure M_GS. The sub-gate structure S_GS is positioned on the base insulating layer 101, and the main gate structure M_GS may be positioned on the sub-gate structure S_GS. As shown in the cross-sectional view of FIG. 4, the main gate structure M_GS may be positioned on the field insulating layer 105. A side of the sub-gate structure S_GS may be covered by a portion of the main gate structure M_GS positioned on the field insulating layer 105. The sub-gate structure S_GS may not be positioned on the field insulating layer 105. For example, a sub-gate structure S_GS may not be positioned between the main gate structure M_GS and the field insulating layer 105.

Each of the sub-gate structures S_GS may be formed of a plurality of layers. For example, each of the sub-gate structure S_GS may include a sub-gate electrode 120S and a sub-gate insulating layer 130S. The sub-gate structures S_GS and the channel patterns 110a, 110b, 110c, 110d may be alternately stacked in the third direction D3. In FIGS. 2 and 4, four sub-gate structures S_GS are shown to be arranged spaced apart in the third direction D3, but the number of sub-gate structures S_GS arranged spaced apart is not limited thereto. For example, the gate structure GS may include three sub-gate structures S_GS.

The sub-gate electrode 120S may be positioned on the protruding pattern PP. On the protruding pattern PP, a plurality of sub-gate electrodes 120S may be positioned spaced apart. A plurality of sub-gate electrodes 120S and a plurality of channel patterns 110a, 110b, 110c, 110d may be alternately repeatedly stacked. At least one of the upper surface and the lower surface of the plurality of channel patterns 110a, 110b, 110c, 110d may be covered by the sub-gate electrode 120S. For example, the lower surface of the first channel pattern 110a may be covered by the sub-gate electrode 120S, and the upper surface of the fourth channel pattern 110d may be covered by the sub-gate electrode 120S. The upper surface and the lower surface of each of the second channel pattern 110b and the third channel pattern 110c may be covered by the sub-gate electrode 120S.

The sub-gate electrode 120S may include at least one of a metal, a metal alloy, a conductive metal nitride, a metal silicide, a doped semiconductor material, a conductive metal oxide, and a conductive metal oxynitride. The sub-gate electrode 120S may include at least one selected from the group consisting of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The conductive metal oxide and the conductive metal oxynitride may include an oxidized form of the aforementioned material, but are not limited thereto.

The sub-gate insulating layer 130S may be positioned along the periphery of the plurality of channel patterns 110a, 110b, 110c, 110d. The sub-gate insulating layer 130S may directly contact the plurality of channel patterns 110a, 110b, 110c, 110d. The sub-gate insulating layer 130S may be interposed between the plurality of channel patterns 110a, 110b, 110c, 110d and the sub-gate electrode 120S. The sub-gate insulating layer 130S may include various insulating materials. The semiconductor device according to one or more embodiments may further include an inner gate spacer positioned between the sub-gate insulating layer 130S and the source/drain pattern 150 to be described below.

In an example, the sub-gate insulating layer 130S is illustrated as a single layer; however, embodiments are not limited thereto. For example, the sub-gate insulating layer 130S may be formed as a multilayer including silicon oxide (SiO₂) and a high dielectric constant material. At this time, the high dielectric constant material may include a material having a dielectric constant greater than that of silicon oxide (SiO₂), such as hafnium oxide (HfO), aluminum oxide (AlO), or tantalum oxide (TaO).

The main gate structure M_GS may be positioned on the sub-gate structure S_GS and the plurality of channel patterns 110a, 110b, 110c, 110d. The main gate structure M_GS may be positioned on the upper surface of the channel pattern 110a positioned at the topmost among the plurality of channel patterns 110a, 110b, 110c, 110d. The main gate structure M_GS may be positioned on the field insulating layer 105. The main gate structure M_GS may cover opposite side surfaces of the sub-gate structure S_GS.

The main gate structure M_GS may include a main gate electrode 120M and a main gate insulating layer 130M.

The main gate electrode 120M may be positioned on the sub-gate structure S_GS and the plurality of channel patterns 110a, 110b, 110c, 110d. The main gate electrode 120M may extend in a direction intersecting the protruding pattern PP. At least a portion of the main gate electrode 120M may be positioned on a structure in which the sub-gate electrode 120S and the plurality of channel patterns 110a, 110b, 110c, 110d are alternately stacked. The remaining portion of the main gate electrode 120M may cover and/or be provided on a side surface of the structure in which the sub-gate electrode 120S and the plurality of channel patterns 110a, 110b, 110c, 110d are alternately stacked. Four side surfaces of each of the plurality of channel patterns 110a, 110b, 110c, 110d may be surrounded by and be adjacent to the sub-gate electrode 120S and/or the main gate electrode 120M.

The main gate electrode 120M may include the same material as the sub-gate electrode 120S. For example, the main gate electrode 120M may include one of a metal, a metal alloy, a conductive metal nitride, a metal silicide, a doped semiconductor material, a conductive metal oxide, and a conductive metal oxynitride.

The main gate insulating layer 130M may be extended along a side surface of the main gate electrode 120M. The main gate insulating layer 130M may extend along the side surface of the gate spacer 142 to be described below. The main gate insulating layer 130M may include various insulating materials. The main gate insulating layer 130M may include the same material as the sub-gate insulating layer 130S.

In an embodiment, although the main gate insulating layer 130M is illustrated as a single layer, but embodiments are not limited thereto. For example, the main gate insulating layer 130M may be formed of a multilayer including silicon oxide (SiO₂) and a relatively high dielectric constant material. At this time, the relatively high dielectric constant material may include a material having a dielectric constant greater than a dielectric constant of silicon oxide (SiO₂), such as hafnium oxide (HfO), aluminum oxide (AlO), or tantalum oxide (TaO).

A semiconductor device according to one or more embodiments may further include a capping layer 141 and a gate spacer 142.

The gate spacer 142 may be positioned on a side surface of the main gate electrode 120M. The gate spacer 142 may be positioned on the channel structure CH. The gate spacer 142 may not be positioned on a side surface of the sub-gate electrode 120S. The gate spacer 142 may not be positioned on a side surface of each of the channel patterns 110a, 110b, 110c, and 110d. The gate spacer 142 may not be disposed between the protruding pattern PP and the plurality of channel patterns 110a, 110b, 110c, 110d. The gate spacer 142 may not be disposed between the plurality of channel patterns 110a, 110b, 110c, 110d adjacent in the third direction D3. The gate spacer 142 is shown as a single layer, but embodiments are not limited thereto, and the gate spacer 142 may include multiple layers.

The gate spacer 142 may include, for example, one of silicon nitride (SiN_{X}), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. The gate spacer 142 is illustrated as a single layer, but embodiments are not limited thereto, and the gate spacer 142 may include multiple layers.

The capping layer 141 may be positioned on the main gate structure M_GS and the gate spacer 142. The upper surface and side surface of the capping layer 141 may be covered by the interlayer insulating layer 171 described below. However, embodiments are not limited thereto, and the capping layer 141 may be positioned between the gate spacers 142.

The capping layer 141 may include one of silicon nitride (SiN), silicon oxynitride (SiON), silicon oxycarbonitride (SiOCN), silicon (Si) carbonitride (SiCN), and combinations thereof. The capping layer 141 may include a material having an etching selectivity with respect to the interlayer insulating layer 171 to be described later.

The source/drain patterns 150 may be positioned on the base insulating layer 101. A protruding pattern PP may be positioned between the source/drain patterns 150 and the base insulating layer 101. However, embodiments are not limited thereto, and a protruding pattern PP may not be positioned between the source/drain pattern 150 and the base insulating layer 101. A channel structure CH and a gate structure GS may be positioned between the source/drain patterns 150. A plurality of source/drain patterns 150 and a plurality of channel structures CH may be alternately arranged along a first direction D1 in which a protruding pattern PP extends.

The source/drain patterns 150 may also be arranged in the second direction D2. Referring to FIGS. 1 and 3, a plurality of protruding patterns PP may be arranged spaced apart from each other along a second direction D2 on the base insulating layer 101, and source/drain patterns 150 may be positioned on each of the protruding patterns PP.

The source/drain pattern 150 may be positioned at opposite sides of the channel structure CH, or the sub-gate structure S_GS. For example, two source/drain patterns 150 positioned on one protruding pattern PP may be arranged spaced apart from each other with the channel structure CH or the sub-gate structure S_GS interposed therebetween, in a direction (for example, the first direction D1) intersecting the direction in which the gate structure GS extends. The source/drain pattern 150 may directly contact the channel structure CH or the sub-gate structure S_GS. The source/drain pattern 150 may be in direct contact with the sub-gate insulating layer 130S of the sub-gate structure S_GS. For example, an inner spacer may further be disposed between the source/drain pattern 150 and the sub-gate insulating layer 130S. The inner spacer may include one of silicon nitride (SiN_{X}), silicon oxynitride (SiON), silicon oxide (SiO₂), silicon oxycarbonitride (SiOCN), silicon boron nitride (SiBN), silicon oxyboronitride (SiOBN), silicon oxycarbide (SiOC), and combinations thereof.

A semiconductor device according to one or more embodiments may include a plurality of source/drain patterns 150 spaced apart and arranged along a first direction D1. In one or more embodiments, at least one of the source/drain patterns 150 may be connected to the upper wiring structure 410, which will be described later, and at least one may be connected to the lower wiring structure 420, which will be described later. Referring to FIGS. 2 and 3, the first source/drain pattern 151 may be connected to the upper wiring structure. Referring to FIGS. 2 and 3, an upper region of the first source/drain pattern 151 may be connected to the upper wiring structure 410 through the upper contact electrode 191, which will be described below. The upper region of the first source/drain pattern 151 may surround at least a portion of the lower surface and side surface of the upper contact electrode 191.

A lower region of the second source/drain pattern 152 may be connected to the lower wiring structure through a lower contact electrode 195, which will be described later. A lower region of the second source/drain pattern 152 may be connected to the upper wiring structure 410 through a lower contact electrode 195 to be described later. A lower region of the second source/drain pattern 152 may contact at least a portion of an upper surface of the lower contact electrode 195.

In the semiconductor device according to one or more embodiments, a lower surface of at least one of the source/drain patterns 150 may have a concave shape in a direction toward an upper surface of the source/drain pattern 150. In one or more embodiments, among the source/drain patterns 150, the second source/drain pattern 152 connected to the lower contact electrode 195 may have a concave shape in a direction in which the lower surface faces the upper surface of the second source/drain pattern 152. In the semiconductor device according to one or more embodiments, a contact structure 160, which will be described later, may be positioned inside the concave lower surface shape of the second source/drain pattern 152.

The source/drain pattern 150 may include an epitaxial layer formed by selective epitaxial growth (SEG). For example, the source/drain pattern 150 may be formed in the region by a selective epitaxial growth method after removing at least a portion of the semiconductor pattern positioned on the protruding pattern PP.

The source/drain patterns 150 may each include a liner layer 151a, 152a and a filling layer 151b, 152b. Referring to FIGS. 2 and 3, the first source/drain pattern 151 and the second source/drain pattern 152 may each include a filling layer 151b, 152b and a liner layer 151a, 152a. The liner layer 151a, 152a may be positioned outside the filling layer 151b, 152b. The side surface and lower surface of the filling layer 151b, 152b may be surrounded by and be adjacent to the liner layer 151a, 152a. The liner layer 151a, 152a may directly contact the sub-gate structure S_GS and the channel structure CH. The filling layer 151b, 152b may be positioned on the liner layer 151a, 152a. The filling layer 151b, 152b and the liner layer 151a, 152a may have an upper surface of substantially the same height. However, embodiments are not limited thereto, and, for example, the filling layer 151b, 152b and the liner layer 151a, 152a may have upper surfaces at different heights in some regions.

The source/drain pattern 150 may include a semiconductor material. The source/drain pattern 150 may include, for example, silicon (Si) or germanium (Ge). In addition, the source/drain pattern 150 may include, for example, a binary compound including at least two of carbon (C), silicon (Si), germanium (Ge), and tin (Sn), or a ternary compound. For example, the source/drain pattern 150 may include silicon (Si), silicon germanium (SiGe), germanium (Ge), silicon carbide (SiC), or the like, but is not limited thereto.

In one or more embodiments, the second source/drain pattern 152 may include silicon germanium (SiGe). In one or more embodiments, the content (at %) of germanium (Ge) in the filling layer 152b and the liner layer 152a may be different from each other.

For example, the content of germanium (Ge) in the liner layer 152a may be smaller than the content of germanium (Ge) in the filling layer 152b. For example, the content of germanium (Ge) included in the liner layer 152a may be greater than or equal to 0 at % and less than or equal to about 10 at %. As an example, the average content of germanium (Ge) in the entire region of the liner layer 152a may be about 5 at %. However, this is not limited thereto, and the content of germanium (Ge) included in the liner layer 152a may be variously designed.

For example, the content of germanium (Ge) in the filling layer 152b may be greater than the content of germanium (Ge) in the liner layer 152a. For example, the content of germanium (Ge) in the filling layer 152b may be greater than or equal to about 42 at % and may be less than or equal to about 48 at %. As an example, the average content of germanium (Ge) in the entire region of the filling layer 152b may be about 45 at %. However, embodiments are not limited thereto, and the content of germanium (Ge) included in the filling layer 152b may be variously designed. In one or more embodiments, the content of germanium (Ge) in the filling layer 152b may be substantially the same as the content of germanium (Ge) in the first contact pattern 161 to be described later, but is not limited thereto.

In one or more embodiments, the source/drain patterns 150 may include P-type dopants. For example, each of the source/drain patterns 150 may be doped by P-type impurities. For example, when the source/drain patterns 150 include silicon germanium (SiGe), the source/drain patterns 150 may be doped by at least one of boron (B), gallium (Ga), and indium (In), but are not limited thereto.

In one or more embodiments, the doping concentration of dopants included in the liner layer 151a, 152a and the doping concentration of dopants included in the filling layer 151b, 152b may be different from each other. For example, the doping concentration of dopants included in the filling layer 151b, 152b may be greater than the doping concentration of dopants included in the liner layer 151a, 152a. For example, when the source/drain pattern 150 is doped with a P-type dopant, for instance, boron (B), the doping concentration of the liner layer 151a, 152a may be about 3.0×10¹⁸ cm⁻³. For example, the doping concentration of the filling layer 151b, 152b may be about 1.2×10²¹ cm⁻³.

In one or more other embodiments, the source/drain patterns 150 may include N-type dopants. For example, each of the source/drain pattern 150 may be doped with an N-type impurity. For example, when the source/drain patterns 150 include silicon (Si), the source/drain patterns 150 may be doped by at least one of phosphorus (P), arsenic (As), and antimony (Sb), but are not limited thereto.

The semiconductor device according to the example may further include an etch stop layer positioned on the source/drain patterns 150. The etch stop layer 185 may be positioned between the source/drain patterns 150 and the interlayer insulating layer 171, which will be described later.

The etch stop layer 185 may cover and/or be provided on the source/drain patterns 150. The etch stop layer 185 may be positioned on at least a portion of the upper surface and side surface of the source/drain pattern 150. For example, referring to FIG. 3, the etch stop layer 185 may be positioned on two sides, among the entire region of the side surfaces of the source/drain pattern 150, that overlap with the interlayer insulating layer 171 to be described later in the second direction D2. For example, referring to FIG. 2, the etch stop layer 185 may not be positioned on the two side surfaces of the source/drain pattern 150 among the entire region of the side surfaces, which face the sub-gate structure S_GS and the channel structure CH along the first direction D1.

The etch stop layer 185 may also be positioned on the field insulating layer 105. For example, the etch stop layer 185 may be positioned conformally along at least a portion of the upper surface and side surface of the source/drain pattern 150, and the upper surface of the field insulating layer 105.

The etch stop layer 185 may be positioned on the side surface of the gate spacer 142. The etch stop layer 185 may cover a side surface of the gate spacer 142. Referring to FIG. 2, the etch stop layer 185 may be conformally positioned in the interior of a region defined by one side surfaces of two gate spacers 142 facing each other and the upper surface of the source/drain pattern 150.

For example, the etch stop layer 185 may be omitted. In this case, side surfaces of the source/drain pattern 150 may be covered by the interlayer insulating layer 171 to be described later.

The etch stop layer 185 may include an insulating material. The etch stop layer 185 may include, for example, silicon nitride (SiN), silicon oxynitride (SiON), silicon oxide (SiO₂), silicon oxycarbonitride (SiOCN), silicon boronitride (SiBN), silicon oxoboronitride (SiOBN), silicon oxycarbide (SiOC), and at least one of combinations thereof. The etch stop layer 185 is illustrated as a single layer, but this is merely for convenience of explanation and embodiments are not limited thereto.

A semiconductor device according to one or more embodiments may further include an interlayer insulating layer 171 covering and/or provided on the source/drain pattern 150 and the gate structure GS. The interlayer insulating layer 171 may be positioned on side surfaces of the gate spacer 142, on side surfaces of the capping layer 141, and also on the upper surface thereof.

The interlayer insulating layer 171 may be positioned on the upper surface of the source/drain patterns 150. The interlayer insulating layer 171 may be positioned on a portion of a side surface of the source/drain pattern 150. Referring to FIGS. 2 and 3, the interlayer insulating layer 171 may cover and/or be provided on the entire region of the upper surface and the side surface of the source/drain patterns 150 in a region not overlapping with the gate structures GS in the third direction D3. The interlayer insulating layer 171 may be positioned on the upper surface of the field insulating layer 105.

The interlayer insulating layer 171 may include one of silicon oxide (SiO₂), silicon nitride (SiN_{X}), silicon oxynitride (SiON), and a relatively low dielectric constant material. The relatively low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), polyimide nanofoams such as TOSZ (Tonen SilaZen), FSG (Fluoride Silicate Glass), polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof; however, embodiments are not limited thereto.

In one or more embodiments, the interlayer insulating layer 171 and the field insulating layer 105 may include different insulating materials. However, embodiments are not limited thereto, and in one or more other embodiments, the interlayer insulating layer 171 and the field insulating layer 105 may include the same insulating material. In this case, a boundary between the interlayer insulating layer 171 and the field insulating layer 105 may not be visually recognized.

A semiconductor device according to one or more embodiments may further include an upper contact electrode 191. The upper contact electrode 191 may be positioned on the source/drain pattern 150. The upper contact electrode 191 may be extended into the source/drain pattern 150 to a predetermined depth along the third direction D3. The upper contact electrode 191 may be located between two main gate structures M_GS spaced apart from each other along the first direction D1. The upper contact electrode 191 may have an inclined side surface in which a lower width is narrower than an upper width according to an aspect ratio. For example, the width of the upper contact electrode 191 in the horizontal direction may have a shape that gradually becomes narrower as it is adjacent to the upper surface of the source/drain pattern 150.

In one or more embodiments, the upper contact electrode 191 may electrically connect the first source/drain pattern 151 and the upper wiring structure 410, which will be described hereinafter.

The upper contact electrode 191 may have at least a portion surrounded by and adjacent to the interlayer insulating layer 171. Referring to FIGS. 2 and 3, a portion of the upper surface and side surface of the upper contact electrode 191 may be covered by the interlayer insulating layer 171. In one or more embodiments, a portion of the region of the upper contact electrode 191 extended into the interior of the source/drain pattern 150 may be surrounded by and be adjacent to the source/drain pattern 150.

The semiconductor device according to one or more embodiments may further include a silicide layer positioned between the upper contact electrode 191 and the source/drain pattern 150. In the case where the semiconductor device according to one or more embodiments does not include a silicide layer, as shown in FIG. 2, a portion of a side surface and a lower surface of the upper contact electrode 191 may contact the source/drain pattern 150.

The upper contact electrode 191 may include a conductive material. For example, the upper contact electrode 191 and the upper contact via 193 may include one of a metal, a metal alloy, a conductive metal nitride, a metal silicide, a doped semiconductor material, a conductive metal oxide, and a conductive metal oxynitride.

A semiconductor device according to one or more embodiments may further include an upper contact via 193 positioned on the upper contact electrode 191. The upper contact via 193, together with the upper contact electrode 191, may connect at least one of the source/drain patterns 150 to an upper wiring structure 410 to be described later. Referring to FIG. 1 to FIG. 3, the upper contact electrode 191 and the upper contact via 193 may connect the first source/drain pattern 151 with the upper wiring structure 410.

The upper contact via 193 may be in contact with at least a portion of the upper surface of the upper contact electrode 191. The upper contact via 193 may have side surfaces surrounded by and be adjacent to the interlayer insulating layer 171.

The semiconductor device according to one or more embodiments may further include an upper wiring structure 410 located on the interlayer insulating layer 171. The upper wiring structure 410 may provide an electrical signal, such as voltage or current, to at least one of the source/drain patterns 150. As another example, the upper wiring structure 410 may be configured to provide power for at least one of the source/drain patterns 150. For example, the upper wiring structure 410 may include at least a portion of an front side power delivery network (FSPDN).

The lower surface of the upper wiring structure 410 may contact a portion of the upper surface of the upper contact via 193. The upper wiring structure 410 may include upper conductive patterns 411 and an upper wiring insulating layer 412. The upper conductive patterns 411 may include upper wirings arranged spaced apart in a third direction D3, and upper wiring vias connecting between two upper wirings. The upper conductive patterns 411 may be located between the upper wiring insulating layers 412. The upper wiring insulating layer 412 may surround and be adjacent to the upper conductive patterns 411. For example, the upper wiring insulating layer 412 may cover and/or be provided on the upper conductive patterns 411, and the upper conductive patterns 411 may be located within the upper wiring insulating layer 412.

The upper conductive patterns 411 may include a metal (for example, copper). The upper wiring insulating layer 412 may include at least one of silicon oxide (SiO₂), silicon nitride (SiN_{X}), silicon oxynitride (SiON), or low dielectric layers, for example.

The contact structure 160 may be positioned between the source/drain pattern 150 and the lower contact electrode 195, which will be described later. Referring to FIG. 2, the contact structure 160 may be located between the second source/drain pattern 152 and the lower contact electrode 195. In one or more embodiments, the lower surface of the second source/drain pattern 152 may have a concave shape such that the center portion thereof is recessed toward the upper surface of the second source/drain pattern 152. In the semiconductor device according to one or more embodiments, the contact structure 160 may be located inside the concave lower surface shape of the second source/drain pattern 152. The contact structure 160 may be formed by selectively removing a portion of the lower region of the second source/drain pattern 152 and then forming the contact structure in the removed region through selective epitaxial growth.

In one or more embodiments, the contact structure 160 may include two or more contact patterns 161, 162, 163 arranged in the third direction D3. Referring to FIGS. 2, 3, and 5, the semiconductor device according to one or more embodiments is illustrated as including three contact patterns 161, 162, 163 arranged in a third direction D3, but the number of contact patterns 161, 162, 163 is not limited thereto. For example, the semiconductor device according to an example may include two contact patterns 161, 162, 163 or may include four or more contact patterns 161, 162, 163. For example, the semiconductor device according to an example may include five contact patterns 161, 162, 163. In one or more embodiments, the contact patterns 161, 162, 163 may be sequentially formed in the region by a selective epitaxial growth process after removing a portion of a lower region of the second source/drain pattern 152.

In one or more embodiments, each of the contact patterns 161, 162, 163 included in the contact structure 160 may include semiconductor material. For example, each of the contact patterns 161, 162, 163 may include a material having a maximum value of the valence band greater than that of silicon (Si). In one or more embodiments, in case the contact patterns 161, 162, 163 include a material having a maximum value of a valence band greater than that of silicon (Si), a Schottky barrier at the junction surface with the lower contact electrode 195 may be reduced. In this case, the contact resistance of the semiconductor device according to one or more embodiments may be reduced, and accordingly, the electrical characteristics of the semiconductor device according to one or more embodiments may be improved. For example, in the semiconductor device according to one or more embodiments, the contact patterns 161, 162, 163 may include germanium (Ge). In some embodiments, the second source/drain pattern 152 and contact patterns 161, 162, 163 may include silicon germanium (SiGe). The maximum value of the valence band of silicon germanium (SiGe) may vary depending on the content of germanium (Ge). For example, the maximum value of the valence band of silicon germanium (SiGe) may increase as the content of germanium (Ge) increases. In the semiconductor device according to one or more embodiments, the content of germanium (Ge) included in at least one of the contact patterns 161, 162, 163 may be greater than the content of germanium (Ge) included in the second source/drain pattern 152. This will be described in detail hereinafter.

Referring to FIGS. 2, 3, and 5, a semiconductor device according to one or more embodiments may include a first contact pattern 161, a second contact pattern 162, and a third contact pattern 163 sequentially arranged along a direction exactly opposite to the third direction D3. The first contact pattern 161, the second contact pattern 162, and the third contact pattern 163 may be located inside the concave lower surface shape of the second source/drain pattern 152.

The first contact pattern 161 may be located on a lower surface of the second source/drain pattern 152. The first contact pattern 161 may be located between the second source/drain pattern 152 and the lower contact electrode 195. The upper surface of the first contact pattern 161 may have a convex shape toward the third direction D3. A lower surface of the first contact pattern 161 may have a concave shape toward the third direction D3. In one or more embodiments, the first contact pattern 161 may have a shape in which the letter ‘U’ is substantially inverted vertically. At least a portion of the upper surface and a side surface of the first contact pattern 161 may be in contact with the second source/drain pattern 152. Referring to FIGS. 2 and 5, the upper surface of the first contact pattern 161 and at least a portion of a side surface thereof may be in contact with the filling layer 152b. Of the entire region of the side surface of the first contact pattern 161, a portion that is not in contact with the filling layer 152b may be in contact with the liner layer 152a.

The first contact pattern 161 may overlap with at least a portion of the channel structure CH in the first direction D1. In one or more embodiments, the first contact pattern 161 may overlap at least one of the channel patterns 110a, 110b, 110c, 110d included in the channel structure CH in the first direction D1. Referring to FIG. 2, the first contact pattern 161 is illustrated as overlapping, along the first direction D1, the third channel pattern 110c and the fourth channel pattern 110d positioned below among the channel patterns 110a, 110b, 110c, 110d spaced apart along the third direction D3, but is not limited thereto. For example, the first contact pattern 161 may be overlapped with only the fourth channel pattern 110d among the channel patterns 110a, 110b, 110c, 110d along the first direction D1. For example, the first contact pattern 161 may overlap the first channel pattern 110a, the second channel pattern 110b, and the third channel pattern 110c among the channel patterns 110a, 110b, 110c, 110d along the first direction D1.

Referring to FIG. 5, the first contact pattern 161 may include a first main region 161a, and a first boundary region 161b positioned under the first main region 161a. The first main region 161a may be located directly below the second source/drain pattern 152. The upper surface of the first main region 161a may be in contact with the second source/drain pattern 152. The first boundary region 161b may be located between the first main region 161a and the second contact pattern 162, which will be described later. The first boundary region 161b may be conformally located along the upper surface of the second contact pattern 162. In one or more embodiments, the first boundary region 161b may have a thinner thickness as compared to the thickness of the first main region 161a.

In one or more embodiments, the first main region 161a and the first boundary region 161b may include silicon germanium (SiGe). In one or more embodiments, the content of germanium (Ge) included in the first boundary region 161b may be greater than the content of germanium (Ge) included in the first main region 161a. In the process of forming the contact structure 160 during the manufacturing process of the semiconductor device according to one or more embodiments, after forming the first contact pattern 161, a process stabilization step may be required before forming the second contact pattern 162. The process stabilization step may be a step for stabilizing process equipment (for example, deposition equipment) under the process conditions for forming the second contact pattern 162, before forming the second contact pattern 162 after forming the first contact pattern 161, for example. In the process stabilization step, conditions such as temperature, pressure, and gas composition within the process equipment may reach within a target range and be maintained for a certain period of time, so that uniformity and reproducibility in subsequent processes may be ensured.

After forming the first contact pattern 161, before forming the second contact pattern 162, during the process stabilization step, at least some of the germanium (Ge) atoms included in the first contact pattern 161 may move toward the surface. For example, at least some of the germanium (Ge) atoms included in the first contact pattern 161 may move toward the surface exposed to the outside (that is, the surface in contact with air or vacuum) during the process stabilization step. Accordingly, the content of germanium (Ge) included in the first boundary region 161b may be greater than the content of germanium (Ge) included in the first main region 161a.

Silicon germanium (SiGe) may have a brightness observable through a microscope that varies depending on the content of germanium (Ge). As an example, when observed through a transmission electron microscopy (TEM), silicon germanium (SiGe) may be observed more brightly as the content of germanium (Ge) increases. According to one or more embodiments, the first boundary region 161b may have a greater content of germanium (Ge) compared to the first main region 161a, and accordingly, when observed through transmission electron microscopy, the first boundary region 161b may be observed more brightly than the first main region 161a.

The second contact pattern 162 may be located below the first contact pattern 161. The second contact pattern 162 may be located between the first contact pattern 161 and the lower contact electrode 195. The second contact pattern 162 may be located between the first contact pattern 161 and the third contact pattern 163, which will be described later. The upper surface of the second contact pattern 162 may have a convex shape toward the third direction D3. The lower surface of the second contact pattern 162 may have a concave shape toward the third direction D3. At least a portion of the upper surface and side surface of the second contact pattern 162 may be in contact with the first contact pattern 161. Referring to FIGS. 2 and 5, the upper surface and side surface of the second contact pattern 162 may contact the first contact pattern 161.

In one or more embodiments, the second contact pattern 162 may overlap, in the first direction D1, with at least one of the channel patterns 110a, 110b, 110c, 110d included in the channel structure CH. Referring to FIG. 2, the second contact pattern 162 is illustrated as overlapping, along the first direction D1, with a portion of the third channel pattern 110c and the fourth channel pattern 110d positioned below. However, embodiments are not limited thereto. For example, the second contact pattern 162 may overlap only with the fourth channel pattern 110d along the first direction D1. For example, the second contact pattern 162 may overlap the first channel pattern 110a, the second channel pattern 110b, and the third channel pattern 110c among the channel patterns 110a, 110b, 110c, 110d along the first direction D1.

Referring to FIG. 5, the second contact pattern 162 may include a second main region 162a and a second boundary region 162b located below the second main region 162a. The second main region 162a may be located directly below the first boundary region 161b. The upper surface of the second main region 162a may be in contact with the first boundary region 161b. The second boundary region 162b may be located between the second main region 162a and the third contact pattern 163 to be described later. The second boundary region 162b may be conformally located along the upper surface of the third contact pattern 163. In one or more embodiments, the second boundary region 162b may have a thickness that is thinner compared to the thickness of the second main region 162a.

In one or more embodiments, the second main region 162a and the second boundary region 162b may include silicon germanium (SiGe). In one or more embodiments, the content of germanium (Ge) included in the second boundary region 162b may be greater than the content of germanium (Ge) included in the second main region 162a.

After forming the second contact pattern 162 and before forming the third contact pattern 163, during the process stabilization step, at least some of the germanium (Ge) atoms included in the second contact pattern 162 may move toward the externally exposed surface. Accordingly, the content of germanium (Ge) included in the second boundary region 162b may be greater than the content of germanium (Ge) included in the second main region 162a.

In one or more embodiments, the second boundary region 162b may have a greater content of germanium (Ge) compared to the content of germanium (Ge) included in the second main region 162a, and accordingly, when observed by transmission electron microscopy, the second boundary region 162b may be observed to be brighter than the second main region 162a.

The third contact pattern 163 may be located below the second contact pattern 162. The third contact pattern 163 may be located between the second contact pattern 162 and the lower contact electrode 195. The third contact pattern 163 may be located between the second contact pattern 162 and the third contact pattern 163, which will be described later. The upper surface of the third contact pattern 163 may have a convex shape facing the third direction D3. A lower surface of the third contact pattern 163 may have a concave shape toward the third direction D3. At least a portion of the upper surface and side surface of the third contact pattern 163 may be in contact with the second contact pattern 162. Referring to FIGS. 2 and 5, the upper surface and side surface of the third contact pattern 163 may be in contact with the second contact pattern 162.

In one or more embodiments, the third contact pattern 163 may overlap with at least one of the channel patterns 110a, 110b, 110c, 110d included in the channel structure CH in the first direction D1. Referring to FIG. 2, the third contact pattern 163 is illustrated as overlapping with a portion of the fourth channel pattern 110d positioned at the lowermost along the first direction D1, but is not limited thereto. For example, the third contact pattern 163 may overlap the third channel pattern 110c and the fourth channel pattern 110d along the first direction D1. For example, the third contact pattern 163 may overlap the first channel pattern 110a, the second channel pattern 110b, and the third channel pattern 110c among the channel patterns 110a, 110b, 110c, and 110d along the first direction D1.

Referring to FIG. 5, the third contact pattern 163 may include a third main region 163a and a third boundary region 163b located under the third main region 163a. The third main region 163a may be located directly below the second boundary region 162b. The upper surface of the third main region 163a may contact the second boundary region 162b. The third boundary region 163b may be located between the third main region 163a and a silicide layer 199 to be described hereinafter. The third boundary region 163b may be conformally positioned along at least a portion of the upper surface of the silicide layer 199. The third boundary region 163b may be conformally positioned along a portion of the upper surface of the silicide layer 199 having a convex shape toward the third direction D3. In one or more embodiments, the third boundary region 163b may have a thickness thinner than the thickness of the third main region 163a.

In one or more embodiments, the third main region 163a and the third boundary region 163b may include silicon germanium (SiGe). In one or more embodiments, the content of germanium (Ge) included in the third boundary region 163b may be greater than the content of germanium (Ge) included in the third main region 163a.

After forming the third contact pattern 163, during the process stabilization step before the next process is carried out, at least some of the germanium (Ge) atoms included in the third contact pattern 163 may move toward the exposed surface to the outside. Accordingly, the content of germanium (Ge) included in the third boundary region 163b may be greater than the content of germanium (Ge) included in the third main region 163a. In one or more embodiments, the third boundary region 163b may have a greater content of germanium (Ge) as compared to the third main region 163a, and accordingly, when observed through transmission electron microscopy, the third boundary region 163b may be observed brighter than the third main region 163a.

In one or more embodiments, the content of germanium (Ge) included in the first contact pattern 161 may be substantially equal to the content of germanium (Ge) included in the filling layer 152b of the second source/drain pattern 152.

In the semiconductor device according to one or more embodiments, the content of germanium (Ge) included in each contact pattern 161, 162, 163 may be greater as each contact pattern 161, 162, 163 is adjacent to the lower contact electrode 195. For example, the content of germanium (Ge) included in the second contact pattern 162 may be greater than the content of germanium (Ge) included in the first contact pattern 161. For example, the content of germanium (Ge) included in the third contact pattern 163 may be greater than the content of germanium (Ge) included in the second contact pattern 162.

In one or more embodiments, the content of germanium (Ge) included in the boundary region 161b, 162b, 163b may be less than the content of germanium (Ge) included in the main region 161a, 162a, 163a of the adjacent other contact patterns 161, 162, 163. For example, the content of germanium (Ge) included in the first boundary region 161b may be less than the content of germanium (Ge) included in the second main region 162a. For example, the content of germanium (Ge) included in the second boundary region 162b may be less than the content of germanium (Ge) included in the third main region 163a.

FIG. 6 is a view for illustrating the content of germanium (Ge) included in the contact patterns 161, 162, 163. For example, FIG. 6 may illustrate the content of germanium (Ge) included in the contact patterns 161, 162, 163 of the semiconductor device according to one or more embodiments, according to the thickness direction for example, the third direction D3. In FIG. 6, the x-axis may indicate the distance in the thickness direction for example, the third direction D3 from the upper surface of the first contact pattern 161 to the lower surface of the third contact pattern 163, and the y-axis may indicate the content (at %) of germanium (Ge) included in the contact patterns 161, 162, 163.

Referring to FIG. 6, in one or more embodiments, at the boundaries of each contact pattern 161, 162, 163, the content of germanium (Ge) may be discontinuous. In one or more embodiments, the content of germanium (Ge) included in each contact pattern 161, 162, 163 may gradually increase stepwise as it becomes closer to the lower contact electrode 195.

For example, the average content of germanium (Ge) in the second contact pattern 162 may be greater than the average content of germanium (Ge) in the first contact pattern 161. For example, the average content of germanium (Ge) in the third contact pattern 163 may be greater than the average content of germanium (Ge) in the second contact pattern 162.

In one or more embodiments, the content of germanium (Ge) included in the first contact pattern 161 may be greater than or equal to about 42 at % and less than or equal to about 48 at %. Ideally, in the entire region of the first main region 161a, the content of germanium (Ge) may be constant at about 45 at %, or, due to the germanium (Ge) moving to the surface exposed to the outside during the process stabilization step, may be slightly less than 45 at %. In one or more embodiments, a content of germanium (Ge) may gradually increase from an interface between the first main region 161a and the first boundary region 161b toward an upper surface of the second main region 162a.

In a region adjacent to the interface between the first boundary region 161b and the second main region 162a, the content of germanium (Ge) included in the first boundary region 161b may be less than the average content of germanium (Ge) in the second contact pattern 162. However, embodiments are not limited thereto, and in the region adjacent to the interface, the content of germanium (Ge) included in the first boundary region 161b may be greater than the average content of germanium (Ge) in the second contact pattern 162.

In one or more embodiments, the content of germanium (Ge) included in the second contact pattern 162 may be greater than or equal to about 48 at % and less than or equal to about 54 at %. Ideally, in the entire region of the second main region 162a, the content of germanium (Ge) may be constant at about 51 at %, or may be slightly less than 51 at % due to germanium (Ge) moving to the surface exposed to the outside in the process stabilization step. In one or more embodiments, from the interface between the second main region 162a and the second boundary region 162b, the content of germanium (Ge) may gradually increase as it becomes closer to the upper surface of the third main region 163a.

In a region adjacent to the interface between the second boundary region 162b and the third main region 163a, the content of germanium (Ge) included in the second boundary region 162b may be less than the average content of germanium (Ge) in the third contact pattern 163. However, embodiments are not limited thereto, and in a region where the second boundary region 162b and the third main region 163a are adjacent to the interface, the content of germanium (Ge) included in the second boundary region 162b may be greater than the average content of germanium (Ge) of the third contact pattern 163.

In one or more embodiments, the content of germanium (Ge) included in the third contact pattern 163 may be greater than or equal to about 54 at %, and may be less than or equal to about 60 at %. In the entire region of the third main region 163a, the content of germanium (Ge) may be constant at about 57 at %, or may be slightly less than 57 at % due to the germanium (Ge) moving to the surface during the process stabilization step. In one or more embodiments, a content of germanium (Ge) may gradually increase from an interface between the third main region 163a and the third boundary region 163b toward an upper surface of the silicide layer 199.

In one or more embodiments, the germanium (Ge) content within each main region 161a, 162a, 163a may gradually increase from the upper surface toward the lower surface. However, even in this case, the average content of germanium (Ge) in the second contact pattern 162 is greater than the average content of germanium (Ge) in the first contact pattern 161, and the average content of germanium (Ge) in the third contact pattern 163 may be greater than the average content of germanium (Ge) in the second contact pattern 162.

When the contact structure 160 located between the source/drain pattern 150 and the lower contact electrode 195 includes silicon germanium (SiGe) including silicon germanium (Ge) of high content, the contact resistance of the semiconductor device according to one or more embodiments may be reduced. However, when the contact structure 160 including a high content of germanium (Ge) is positioned near the channel patterns 110a, 110b, 110c, 110d, the influence due to Drain Induced Barrier Lowering (DIBL) may increase, whereby the threshold voltage of the semiconductor device may shift or the leakage current in the OFF state of the semiconductor device may increase.

In the semiconductor device according to one or more embodiments, the content of germanium (Ge) in the contact patterns 161, 162, and 163 may decrease as they are closer to the channel patterns 110a, 110b, 110c, and 110d and may increase as they become closer to the lower contact electrode 195. According to one or more embodiments, while maintaining a low contact resistance between the contact structure 160 and the lower contact electrode 195, the influence of DIBL may be minimized, and accordingly, the electrical characteristics of the semiconductor device according to one or more embodiments may be improved and the reliability may be enhanced.

In addition, as the content of germanium (Ge) included in the contact patterns 161, 162, 163 stepwise increases as it becomes closer to the lower contact electrode 195, the crystallinity of the source/drain pattern 150 and the contact patterns 161, 162, 163 may be improved, and accordingly, the electrical characteristics of the semiconductor device may be improved.

In one or more embodiments, the contact patterns 161, 162, 163 may include P-type dopants. For example, the contact patterns 161, 162, 163 may include the same dopants as the dopants included in the second source/drain pattern 152. For example, each of the contact patterns 161, 162, 163 may be doped by P-type impurities. For example, when the contact patterns 161, 162, 163 include silicon germanium (SiGe), each of the contact patterns 161, 162, 163 may be doped with at least one of boron (B), gallium (Ga), and indium (In), but is not limited thereto.

In one or more embodiments, the contact patterns 161, 162, 163 may have different doping concentrations. In one or more embodiments, the contact patterns 161, 162, 163 may have a higher doping concentration as the lower contact electrode 195 becomes closer. For example, the doping concentration of the second contact pattern 162 may be greater than the doping concentration of the first contact pattern 161. For example, the doping concentration of the third contact pattern 163 may be greater than the doping concentration of the second contact pattern 162. In one or more other embodiments, the doping concentration of the contact patterns 161, 162, 163 may be constant.

In one or more embodiments, the doping concentration of the first contact pattern 161 may be substantially the same as the doping concentration of the filling layer 152b of the second source/drain pattern 152. For example, the doping concentration of the first contact pattern 161 may be about 1.2×10²¹ cm⁻³.

Referring again to FIG. 1 to FIG. 5, the semiconductor device according to one or more embodiments may further include a silicide layer 199 located under the third contact pattern 163. The silicide layer 199 may be located between the lower contact electrode 195 and the contact patterns 161, 162, 163. The silicide layer 199 may contact the upper surface of the lower contact electrode 195.

In one or more embodiments, the silicide layer 199 may be a metal silicide layer. For example, the silicide layer 199 may include at least one of tungsten silicide (WSi), nickel silicide (NiSi), and/or titanium silicide (TiSi).

A semiconductor device according to one or more embodiments may further include a lower wiring structure 420 positioned on the lower surface of the base insulating layer 101. The lower wiring structure 420 may be configured to supply power to at least one of the source/drain patterns 150. For example, the lower wiring structure 420 may include at least a portion of the back side power delivery network (BSPDN).

The upper surface of the lower wiring structure 420 may contact a portion of the lower surface of the lower contact electrode 195. The lower wiring structure 420 may include lower conductive patterns 421 and a lower wiring insulating layer 422. The lower conductive patterns 421 may include lower wirings arranged spaced apart from each other in a third direction D3, and lower wiring vias connecting between two of the lower wirings. The lower conductive patterns 421 may be located between the lower wiring insulating layers 422. The lower wiring insulating layer 422 may surround and be adjacent to the lower conductive patterns 421. That is, the lower wiring insulating layer 422 may cover and/or be provided on the lower conductive patterns 421, and the lower conductive patterns 421 may be located within the lower wiring insulating layer 422.

The lower conductive patterns 421 may include a metal (for example, copper). The lower wiring insulating layer 422 may include at least one of silicon oxide (SiO₂), silicon nitride (SiN_{X}), silicon oxynitride (SiON), or low dielectric layers, for example.

A semiconductor device according to one or more embodiments may include a lower contact electrode 195 connecting a lower wiring structure 420 and a source/drain pattern 150. The lower contact electrode 195 may connect at least one of the source/drain patterns 150 to the lower wiring structure 420. Referring to FIGS. 2 and 3, the second source/drain pattern 152 may be connected to the lower wiring structure 420 by the lower contact electrode 195. Referring to FIGS. 2 and 4, the lower contact electrode 195 may penetrate the base insulating layer 101 in the third direction D3, and may be connected to the second source/drain pattern 152. The lower contact electrode 195 may have a rectangular planar shape, however, embodiments are not limited thereto, and the lower contact electrode 195 may also have a circular shape or another polygonal shape other than a rectangular shape.

In one or more embodiments, the lower contact electrode 195 may include a first portion 195a positioned on an upper surface of the lower wiring structure 420, and a second portion 195b positioned on an upper surface of the first portion 195a. The first portion 195a may extend into the base insulating layer 101 along the third direction D3 from the upper surface of the lower wiring structure 420. The first portion 195a may penetrate the base insulating layer 101.

The first portion 195a may have an inclined side surface such that the width of the upper region becomes narrower than the width of the lower region according to the aspect ratio. Referring to FIG. 3, on the same plane as the interface between the upper surface of the base insulating layer 101 and the lower surface of the field insulating layer 105, the width of the first portion 195a in the second direction D2 may be narrower than the width of the protruding pattern PP in the second direction D2. In one or more embodiments, the first portion 195a may penetrate the base insulating layer 101 and may be further extended into the inside of the protruding pattern PP along the third direction D3. In a region where the first portion 195a overlaps with the field insulating layer 105 in the second direction D2, a side surface of the first portion 195a may be surrounded by and be adjacent to the protruding pattern PP.

In one or more embodiments, the upper surface of the first portion 195a may be located at a level substantially the same as, or at a lower level than, the lower surface of the source/drain pattern 150. Referring to FIGS. 2 and 3, the first portion 195a may not include a region overlapping with the source/drain pattern 150 in the first direction D1, or the second direction D2. In one or more embodiments, the width of the upper surface of the first portion 195a in the second direction D2 may be greater than or equal to the maximum width of the first contact pattern 161 in the second direction D2. In one or more embodiments, the minimum width of the first portion 195a in the first direction D1 may be greater than or equal to the maximum width of the first contact pattern 161 in the first direction D1.

The second portion 195b may be located on the upper surface of the first portion 195a. The lower surface of the second portion 195b may be in contact with at least a portion of the upper surface of the first portion 195a. At a level where the lower surface of the second portion 195b is located, the width of the second portion 195b in the first direction D1 or the second direction D2 may be smaller than the width of the first portion 195a in the first direction D1 or the second direction D2.

The second portion 195b may protrude in the third direction D3 from the upper surface of the first portion 195a. In one or more embodiments, the lower surface of the silicide layer 199 may include a concave shape in the third direction D3, and the second portion 195b may fill the inside of the concave shape. A width of the second portion 195b in a first direction D1 or a second direction D2 may gradually decrease as it becomes closer to an upper surface of the second source/drain pattern 152.

The lower contact electrode 195 may include one of a metal, a metal alloy, a conductive metal nitride, a conductive metal carbide, a conductive metal oxide, a conductive metal carbonitride, and a two-dimensional (2D) material. The metal may include one of titanium (Ti), tantalum (Ta), tungsten (W), nickel (Ni), cobalt (Co), and platinum (Pt). The conductive metal nitride may include at least one selected from titanium nitride (TiN), tantalum nitride (TaN), tungsten nitride (WN), nickel nitride (NiN), cobalt nitride (CoN), and platinum nitride (PtN).

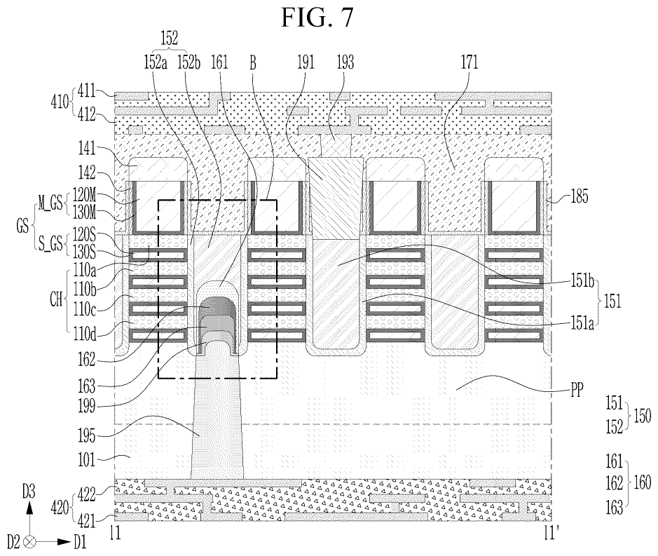

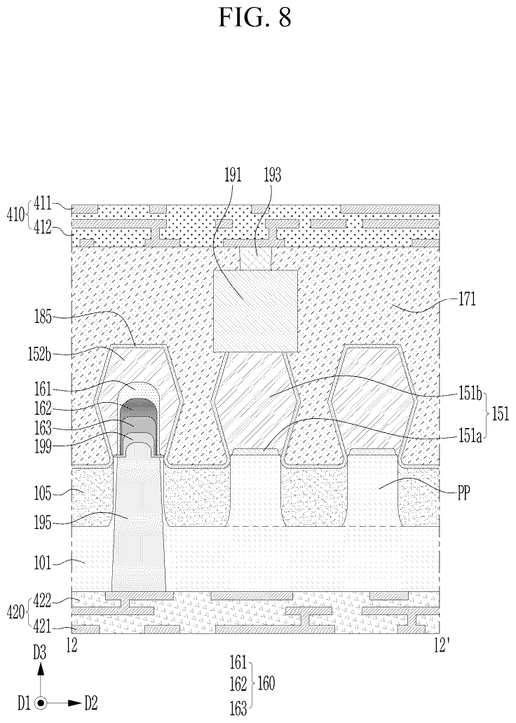

FIGS. 7 and 9 are drawings for illustrating a semiconductor device according to one or more embodiments. For example, FIG. 7 is a cross-sectional view of the semiconductor device taken along line I1-I1′ of FIG. 1, FIG. 8 is a cross-sectional view of the semiconductor device taken along line I2-I2′ of FIG. 1, and FIG. 9 is an enlarged cross-sectional view of the B region of FIG. 8. The semiconductor device shown in FIG. 7 to FIG. 9 is substantially the same as the embodiments described above, so the following description focuses mainly on the differences from the embodiments described above. The semiconductor device shown in FIG. 7 to FIG. 9 may have a width in the horizontal direction of the contact patterns 161, 162, and 163 that is partially different compared to the embodiments described above.

In one or more embodiments, a width W1 according to the horizontal direction of the upper surface of the first portion 195a of the lower contact electrode 195 may be smaller than a maximum width according to the horizontal direction of the contact structure 160. For example, the width W1 in the horizontal direction of the upper surface of the first portion 195a of the lower contact electrode 195 may be less than a maximum width in the horizontal direction among at least any one of the contact patterns 161, 162, 163. Referring to FIG. 7 to FIG. 9, a width W1 according to a horizontal direction of an upper surface of the first portion 195a may be smaller than a maximum width W2 according to a horizontal direction of the first contact pattern 161.

In a manufacturing process of a semiconductor device according to one or more embodiments, in order to form contact patterns 161, 162, 163, a portion of a lower region of a second source/drain pattern 152 may be etched to form a recess RC. At this time, by performing an anisotropic etching process in the vertical direction, for example the third direction D3, after etching a portion of the lower region of the second source/drain pattern 152, an additional etching process in the horizontal direction (for example, the first direction D1, or the second direction D2) may be performed to widen the width of the recess RC in the horizontal direction. Thereafter, using a selective epitaxial growth method, contact patterns 161, 162, and 163 may be formed in the recess RC, and accordingly, as shown in FIG. 7 to FIG. 9, the maximum width in the horizontal direction of the first contact pattern 161 may be formed to be wider than the width in the horizontal direction of the upper surface of the first portion 195a.

In the cross-sectional view shown in FIGS. 7 and 9, a side surface of the first contact pattern 161 may contact the liner layer 152a of the second source/drain pattern 152. In one or more embodiments, the first contact pattern 161 may have a side surface extending in the first direction D1 into the inside of the liner layer 152a of the second source/drain pattern 152. Accordingly, the width in the horizontal direction W3 of a portion of the liner layer 152a overlapping the first contact pattern 161 in the horizontal direction may be less than or equal to the width in the horizontal direction W4 of a portion of the liner layer 152a positioned at a level higher than an upper surface of the first contact pattern 161.

The thickness of liner layer 152a may be formed thicker in the lower region of the source/drain pattern 150 than in the upper region. The liner layer 152a may have a relatively low content of germanium (Ge) compared to the filling layer 152b.

According to one or more embodiments, a portion of the liner layer 152a having a relatively small content of germanium (Ge) may be replaced with the contact patterns 161, 162, 163 having a relatively large content of germanium (Ge). In this case, a compressive stress may be induced in the direction of the channel pattern 110 (for example, the first direction D1), so that the electrical characteristics of the PMOS transistor structure may be improved.

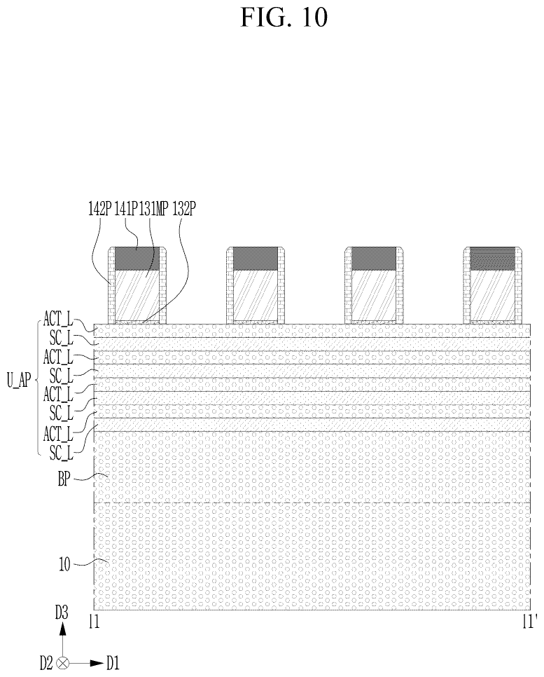

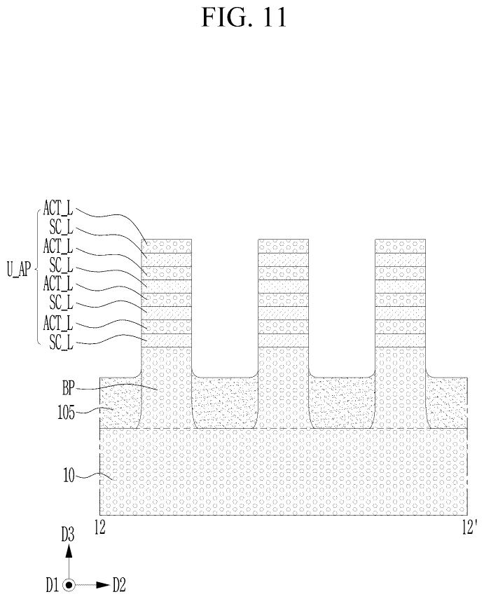

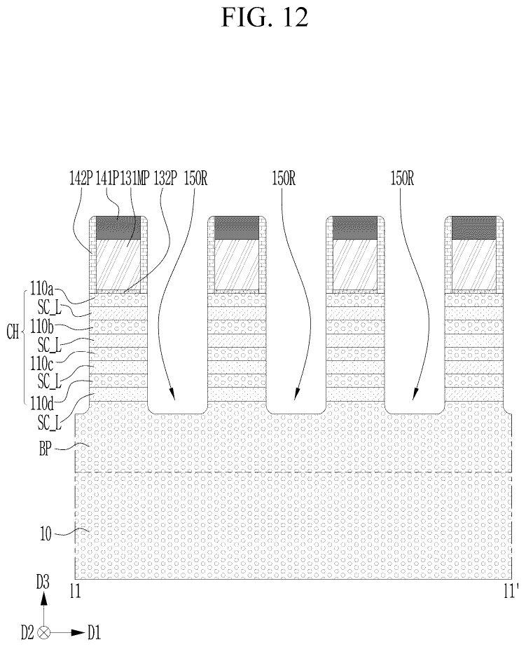

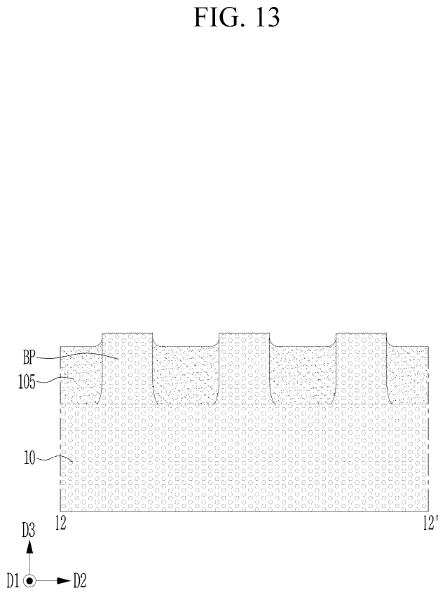

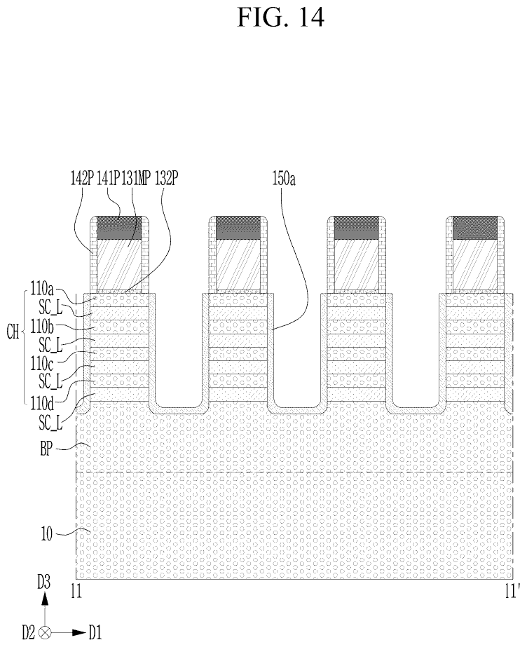

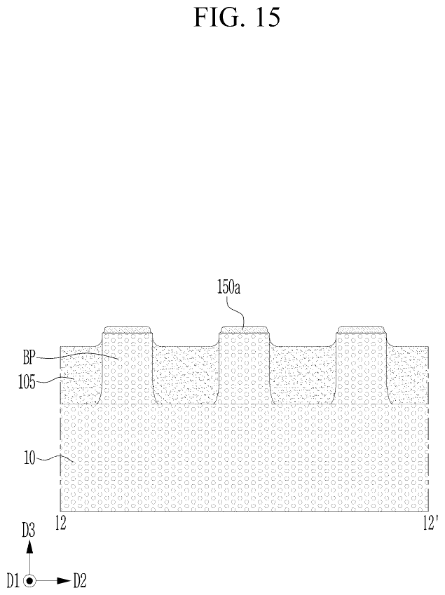

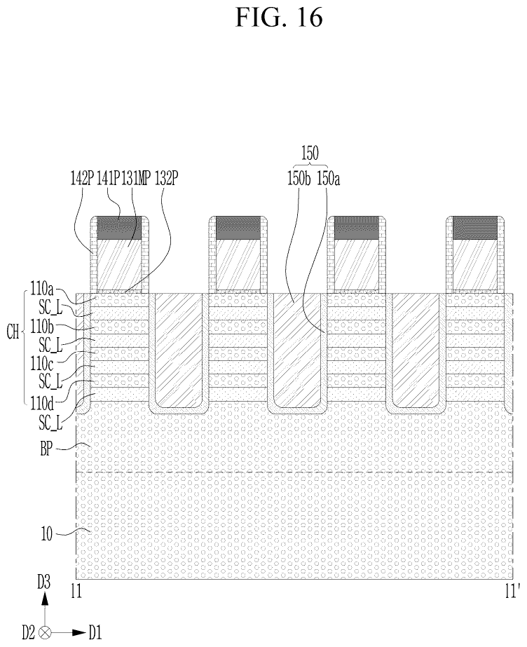

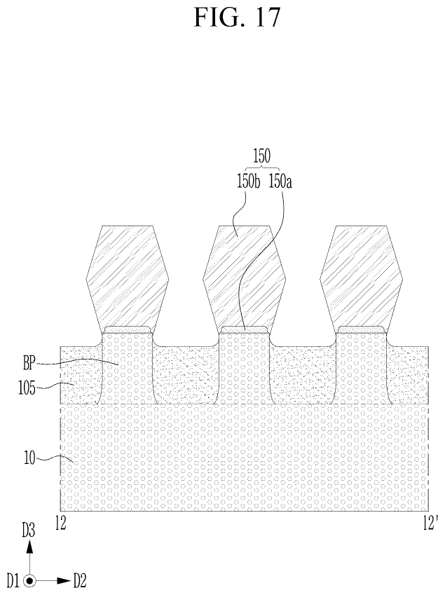

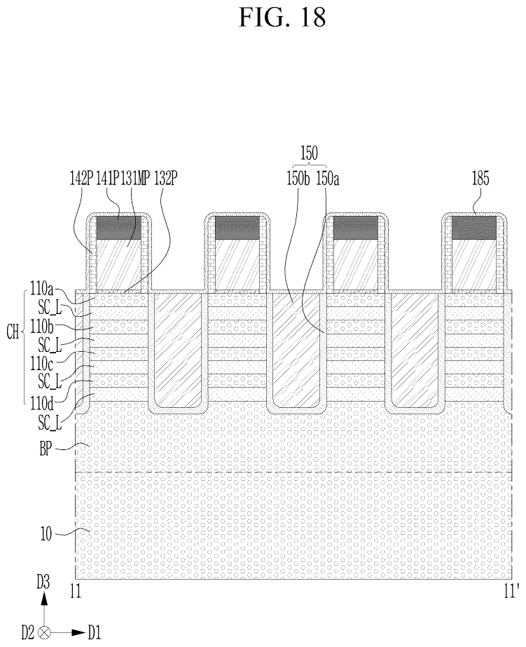

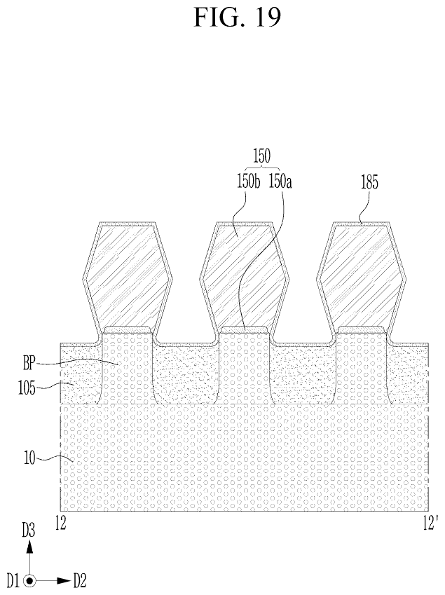

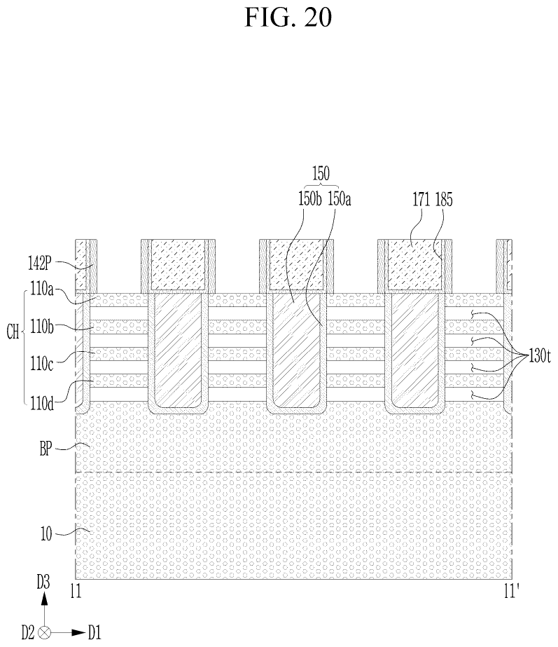

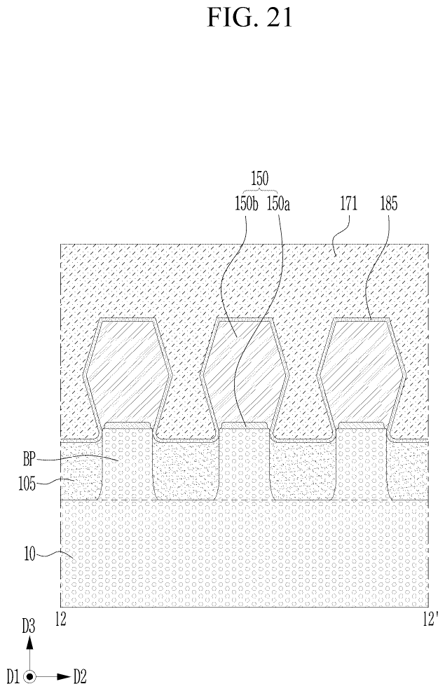

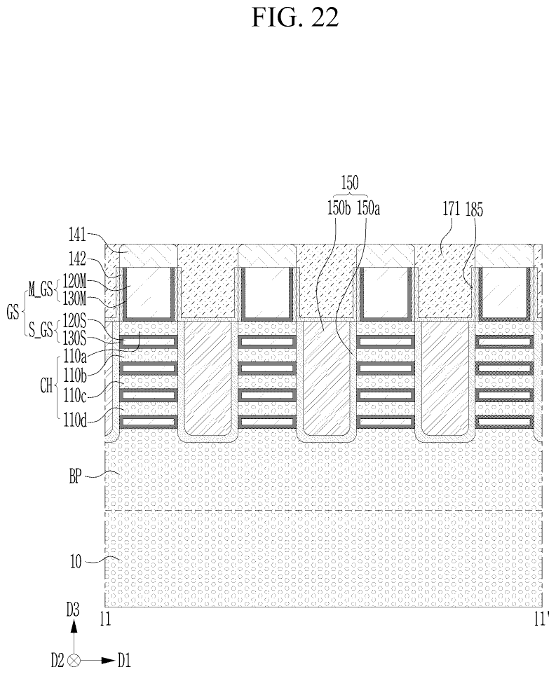

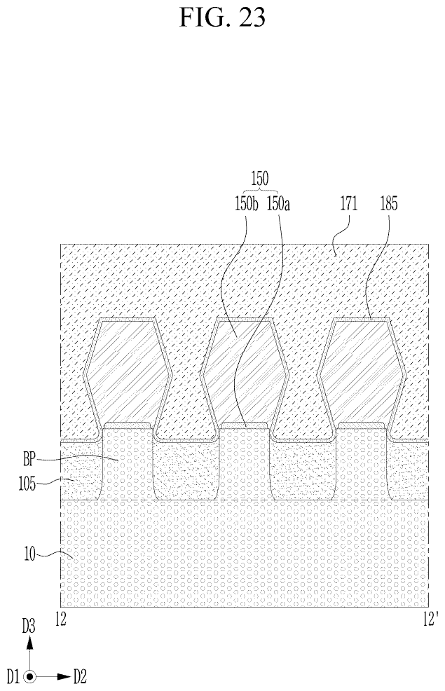

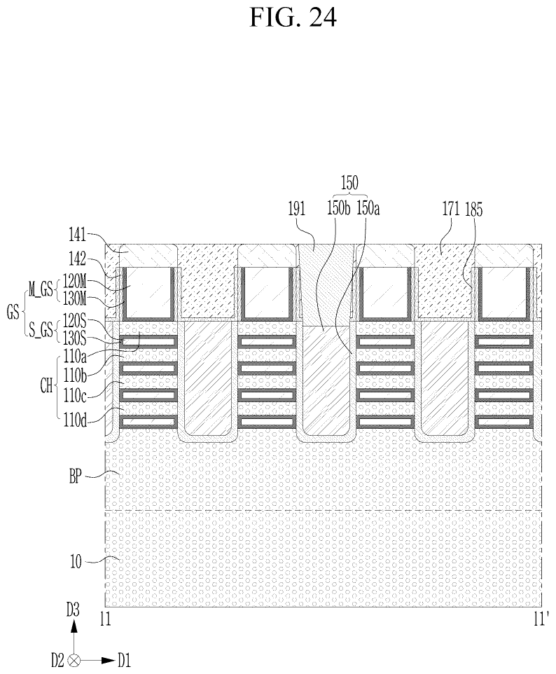

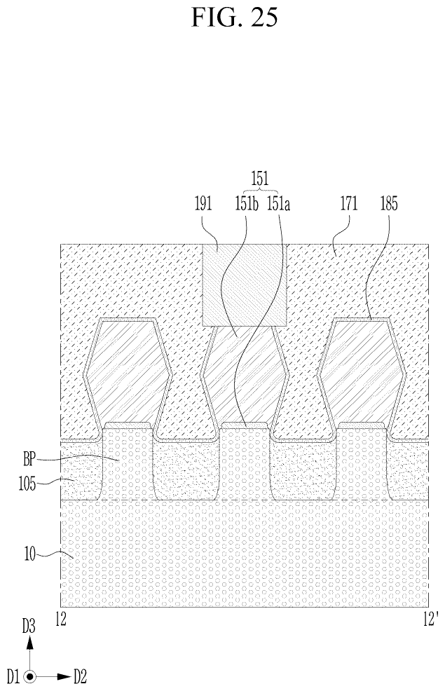

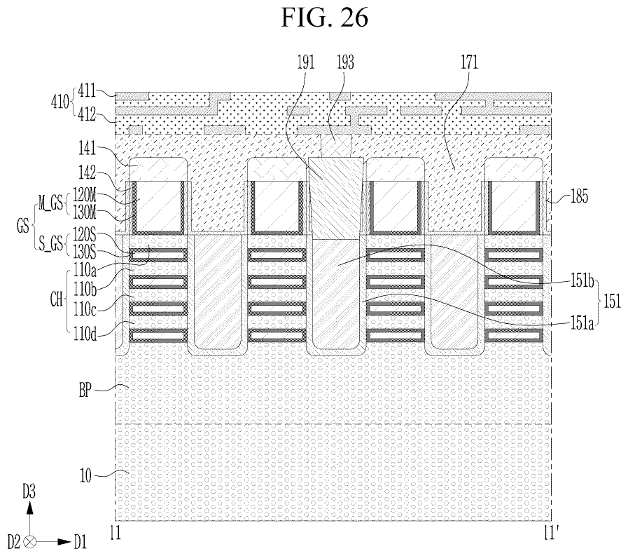

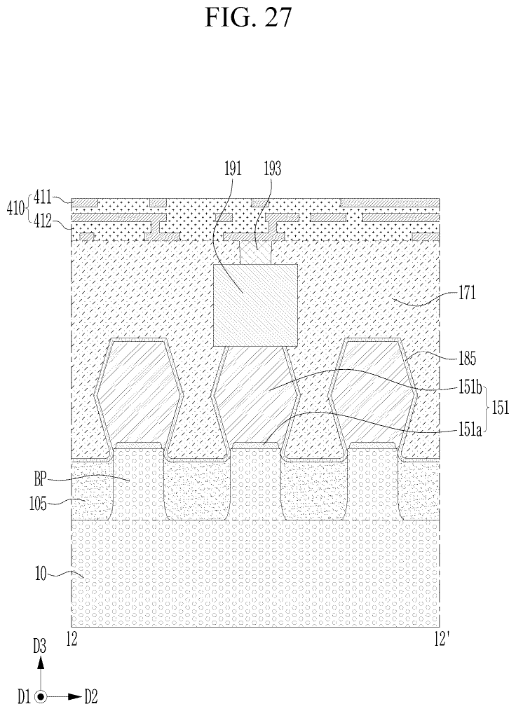

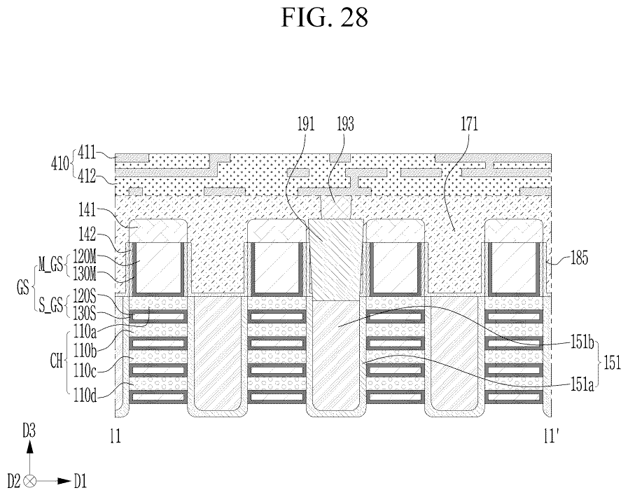

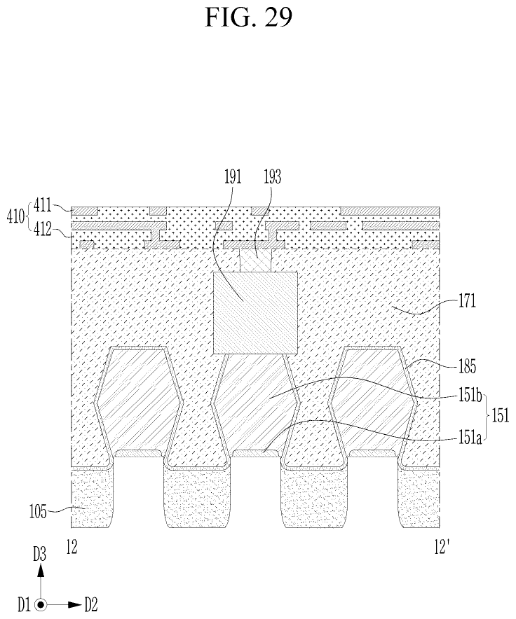

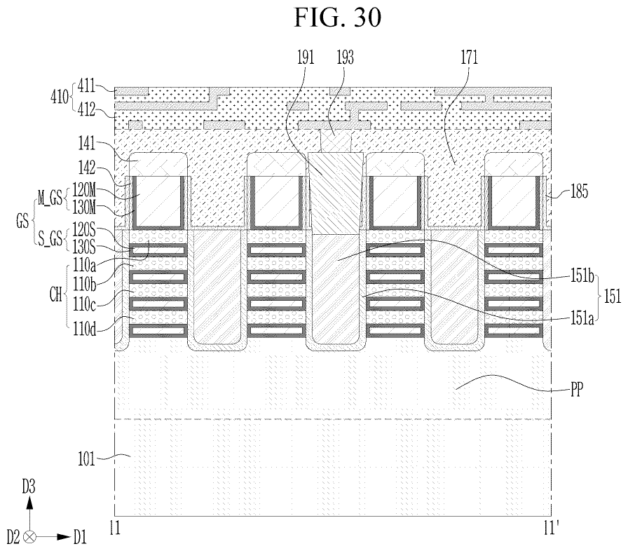

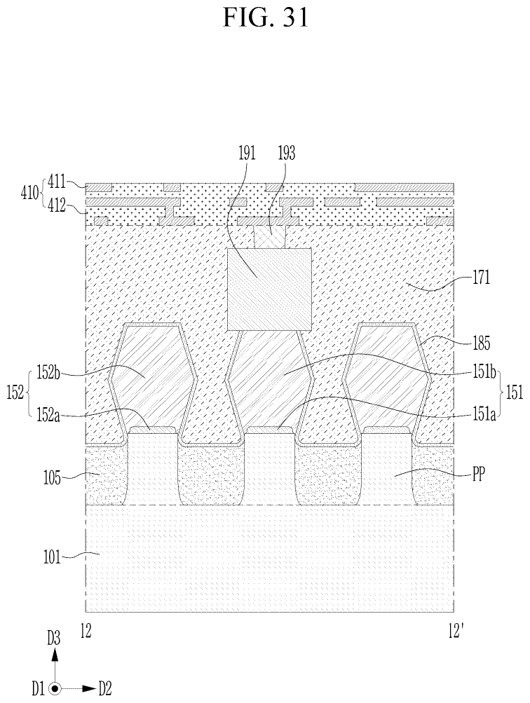

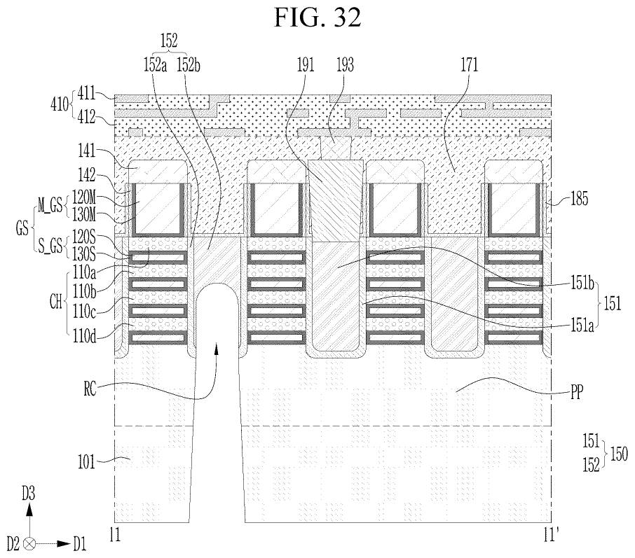

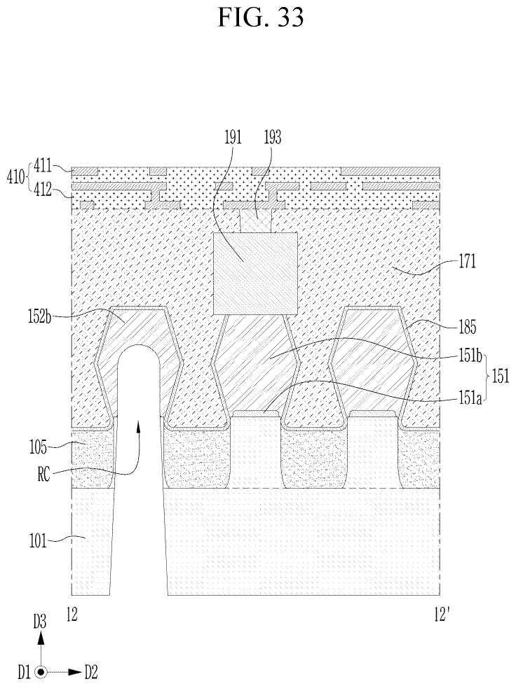

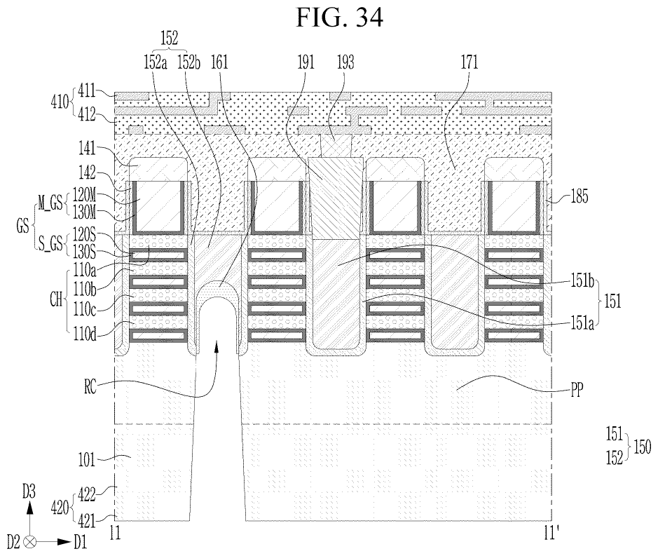

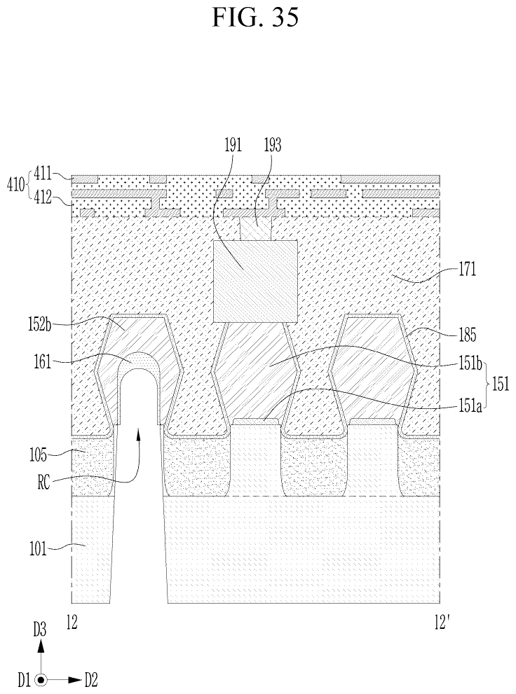

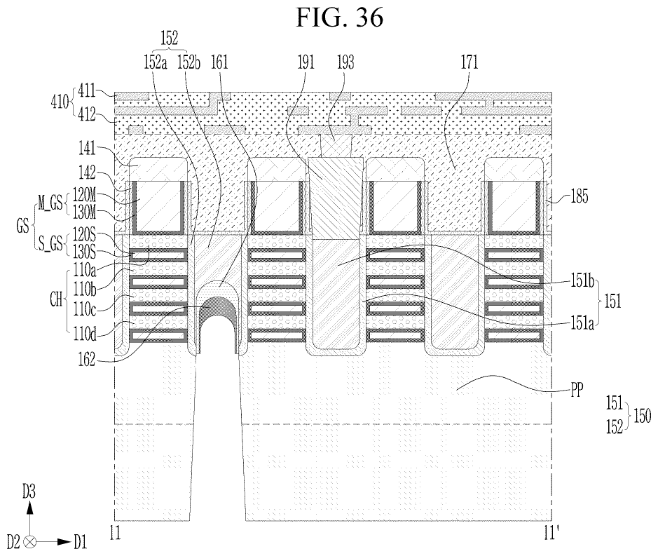

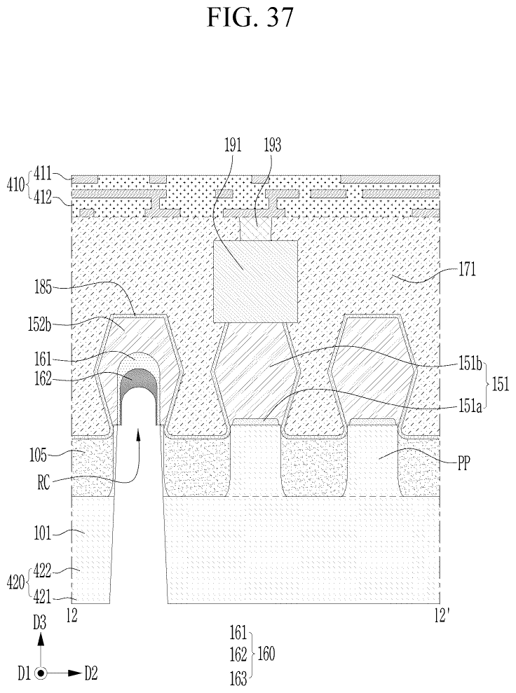

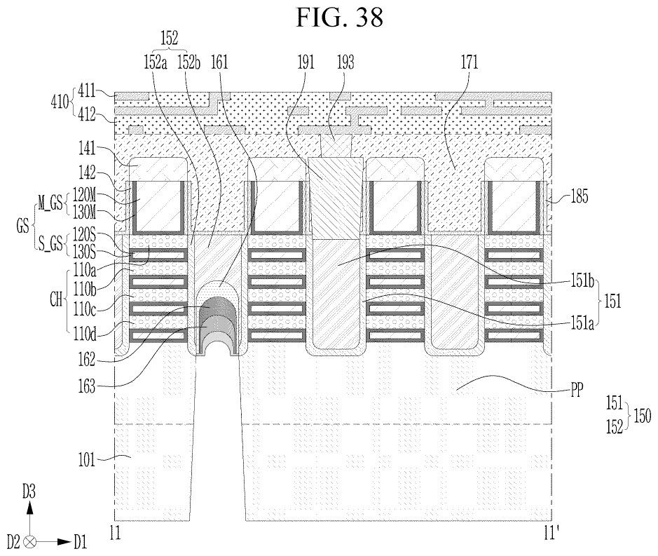

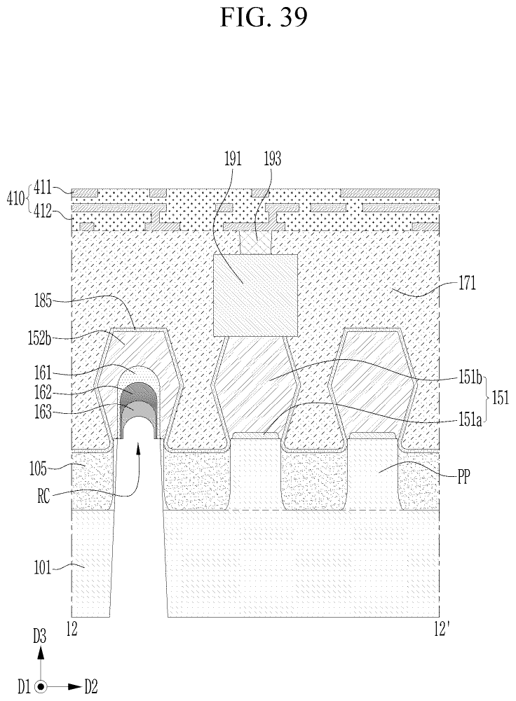

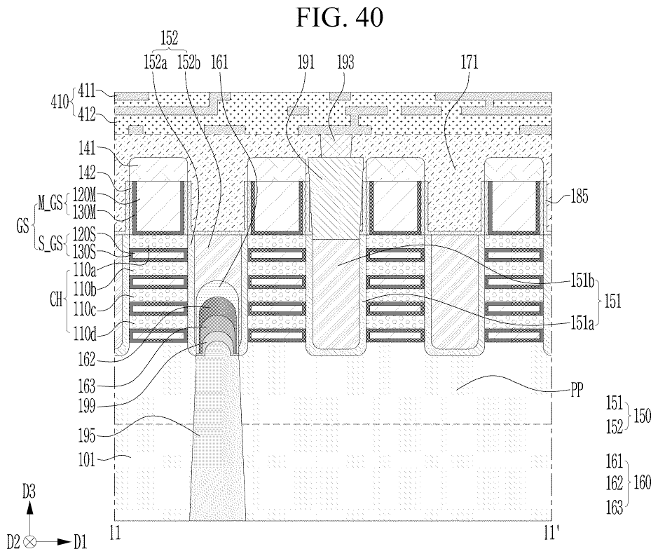

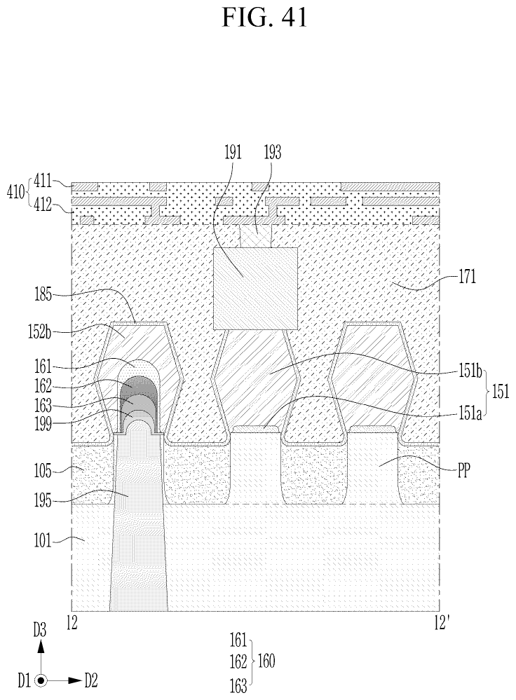

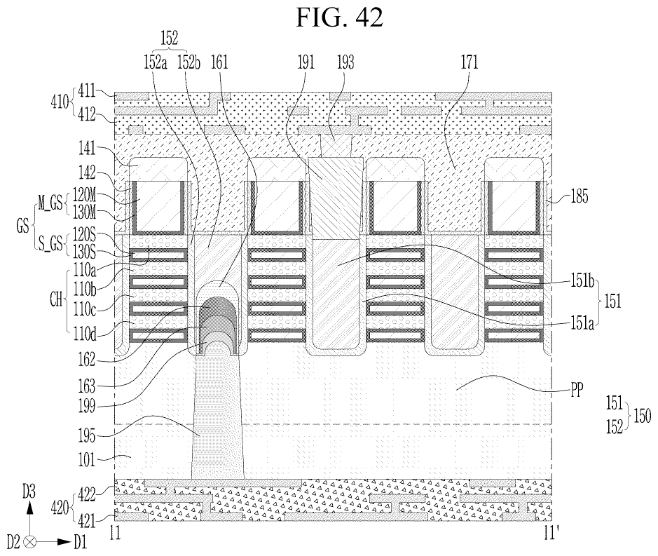

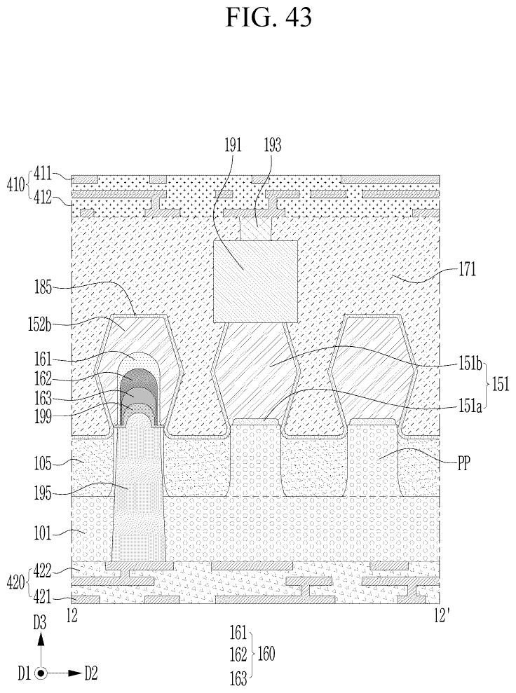

FIG. 10 to FIG. 43 are drawings for illustrating the method of manufacturing a semiconductor device according to one or more embodiments. FIG. 10, FIG. 12, FIG. 14, FIG. 16, FIG. 18, FIG. 20, FIG. 22, FIG. 24, FIG. 26, FIG. 28, FIG. 30, FIG. 32, FIG. 34, FIG. 36, FIG. 38, FIG. 40, and FIG. 42 are cross-sectional views corresponding to regions cut along I1-I1′ of FIG. 1, and FIG. 11, FIG. 13, FIG. 15, FIG. 17, FIG. 19, FIG. 21, FIG. 23, FIG. 25, FIG. 27, FIG. 29, FIG. 31, FIG. 33, FIG. 35, FIG. 37, FIG. 39, FIG. 41, and FIG. 43 are cross-sectional views corresponding to regions cut along I2-I2′ of FIG. 1.

As shown in FIGS. 10 and 11, a lower pattern BP and an upper pattern structure U_AP may be formed on the substrate 10.

For example, a sacrificial pattern SC_L and an active pattern ACT_L may be alternately stacked on the substrate 10 by an epitaxial growth method, and then a portion may be etched to form the upper pattern structure U_AP. At this time, a portion of the substrate 10 may be etched so that a lower pattern BP may be formed. As another example, the lower pattern BP may be formed by being grown through an epitaxial growth method on the substrate 10, and then being etched together when the sacrificial pattern SC_L and the active pattern ACT_L are etched.

The substrate 10 may be silicon-on-insulator (SOI) or bulk silicon. As another example, the substrate 10 may be a silicon substrate or may be formed of another material, for example, silicon germanium (SiGe), silicon germanium on insulator (SGOI), indium antimonide, lead telluride compound, indium arsenide, indium phosphide, gallium arsenide, or gallium antimonide, including but not limited thereto.

The lower pattern BP may include silicon (Si) or germanium (Ge), which is a semiconductor material. As another example, the lower patterns BP may include a compound semiconductor. For example, the lower patterns BP may include a group IV-IV compound semiconductor or a group III-V compound semiconductor. A group IV-IV compound semiconductor may be, for example, a binary compound including carbon (C), silicon (Si), germanium (Ge), tin (Sn), or a combination thereof, or a ternary compound. A group III-V compound semiconductor may be, for example, a binary compound, a ternary compound, or a quaternary compound formed by combining a group III element such as aluminum (Al), gallium (Ga), indium (In), or a combination thereof and a group V element such as phosphorus (P), arsenic (As), antimony (Sb), or a combination thereof. The sacrificial pattern SC_L may include silicon germanium (SiGe). The active pattern ACT_L may include silicon (Si).

Next, a field insulating layer 105 may be formed to cover the upper surface of the substrate 10 and at least a portion of the side surface of the lower pattern BP. The field insulating layer 105 may be formed, by first, depositing an insulating layer on the substrate 10, the lower pattern BP and the upper pattern structure U_AP, and then etching a portion thereof. The field insulating layer 105 may be formed so as to cover and/or be provided on a portion of the side surface of the upper pattern structure U_AP.

Subsequently, on the upper pattern structure U_AP, a preliminary gate insulating layer 132P, a preliminary main gate electrode 131MP, and a preliminary capping layer 141P may be formed. The preliminary gate insulating layer 132P may include, for example, silicon oxide (SiO₂), but is not limited thereto. The preliminary main gate electrode 131MP may include, for example, polysilicon, but is not limited thereto. The preliminary capping layer 141P may include, for example, silicon nitride (SiN_{X}), but is not limited thereto. On opposite side surfaces of the preliminary main gate electrode 131MP, a preliminary gate spacer 142P may be formed.

As shown in FIGS. 12 and 13, the preliminary capping layer 141P and the preliminary gate spacer 142P may be used as a mask to etch at least a portion of the upper pattern structure U_AP to form a source/drain recess 150R. For example, a portion of the upper pattern structure U_AP located between two preliminary main gate electrodes 131MP arranged along the first direction D1 may be etched.

As the source/drain recess 150R is formed, the active pattern ACT_L is separated, and channel structures CH may be formed. The channel structures CH may be respectively positioned at opposite sides of the source/drain recess 150R. A plurality of channel patterns 110a, 110b, 110c, 110d included in the channel structure CH and a sacrificial pattern SC_L may be alternately stacked in a third direction D3. At this time, the respective lengths of the plurality of channel patterns 110a, 110b, 110c, 110d may be different or may be the same.

According to one or more embodiments, a portion of the lower pattern BP may be etched in the process of forming the source/drain recess 150R. For example, as shown in FIGS. 12 and 13, the lower pattern BP may be etched to a predetermined depth in an upper surface direction of the substrate 10. Referring to FIGS. 12 and 13, the bottom surface of the source/drain recess 150R may be located at a level higher than the interface between the substrate 10 and the lower pattern BP.

As shown in FIGS. 14 and 15, a source/drain pattern 150 may be formed in the source/drain recess 150R (see FIG. 10). For example, the liner layer 150a may be formed in the entire region of the source/drain pattern 150 (see FIG. 2).

Referring to FIG. 14, a liner layer 150a may be conformally formed along the inner wall of the source/drain recess 150R. At this time, the channel patterns 110a, 110b, 110c, 110d positioned on the inner wall of the source/drain recess 150R and the lower pattern BP may be used as a seed. For example, referring to FIG. 14, in a cross-sectional view according to the first direction D1 and the third direction D3, the channel patterns 110a, 110b, 110c, 110d and the lower pattern BP as a seed may have liner layers 151a, 152a formed.

Referring to FIG. 15, in a cross-sectional view taken along a first direction D1 and a third direction D3, a liner layer 151a, 152a may be formed using a lower pattern BP as a seed. For example, as described with reference to FIGS. 11 and 12, after a portion of the lower pattern BP is recessed, a liner layer 151a, 152a may be formed along the inner wall of the remaining lower pattern BP. In the process of forming the source/drain recess 150R described with reference to FIGS. 12 and 13, since a portion of the upper pattern structure U_AP located between two preliminary main gate electrodes 131MP arranged along the first direction D1 is removed, in the cross-sectional view taken in the second direction D2 and the third direction D3, channel patterns 110a, 110b, 110c, 110d as illustrated in FIG. 14 may not be located on the lower pattern BP. Accordingly, as illustrated in FIG. 15, in a cross-sectional view taken in the second direction D2 and the third direction D3, the liner layer 151a, 152a may be formed only on the upper surface of the lower pattern BP.

The liner layer 150a may be in direct contact with the channel patterns 110a, 110b, 110c, 110d and the sacrificial patterns SC_L. The liner layer 150a may include silicon (Si), germanium (Ge), or silicon germanium (SiGe). In one or more embodiments, the liner layer 150a may include silicon germanium (SiGe). In one or more embodiments, the content of germanium (Ge) included in the liner layer 150a may be greater than 0 and less than or equal to about 10 at %. As an example, the average content of germanium (Ge) in the entire region of the liner layer 152a may be about 5 at %. However, the present disclosure is not limited thereto, and the content of germanium (Ge) included in the liner layer 152a may be variously designed. In one or more embodiments, the liner layer 150a may be formed on the substrate 10. The liner layer 150a may be formed using a selective epitaxial growth method.

As shown in FIGS. 16 and 17, a filling layer 150b may be formed on the liner layer 150a formed in the source/drain recess 150R (see FIG. 10). The filling layer 150b may be formed using a selective epitaxial growth method. The filling layer 150b may fill a remaining region of the source/drain recess 150R (see FIG. 12) excluding a region where the liner layer 150a is formed. The upper surfaces of the liner layer 150a and the filling layer 150b may have upper surfaces located at substantially the same level as the upper surface of the channel pattern 110a that is located at the uppermost among the channel patterns 110a, 110b, 110c, 110d. In one or more embodiments, the filling layer 150b may include silicon germanium (SiGe). In one or more embodiments, the content of germanium (Ge) included in the filling layer 150b may be greater than the content of germanium (Ge) included in the liner layer 150a. In one or more embodiments, the content of germanium (Ge) included in the filling layer 150b may be greater than or equal to about 42 at % and may be less than or equal to about 48 at %. As an example, the average content of germanium (Ge) in the entire region of the filling layer 152b may be about 45 at %. However, it is not limited thereto, and the content of germanium (Ge) included in the filling layer 152b may be variously designed.

As shown in FIGS. 18 and 19, an etch stop layer 185 covering the preliminary capping layer 141P, the preliminary gate spacer 142P, and the source/drain pattern 150 may be formed. In one or more embodiments, the etch stop layer 185 may be conformally formed on the upper surface of the preliminary capping layer 141P, the side surface of the preliminary gate spacer 142P, and the upper surface and side surface of the source/drain pattern 150. Referring to FIG. 19, the etch stop layer 185 may be formed on the upper surface of the field insulating layer 105.

As shown in FIGS. 20 and 21, a first interlayer insulating layer 171 may be formed on the source/drain pattern 150. Subsequently, a portion of the first interlayer insulating layer 171 and the preliminary capping layer 141P may be removed to expose the upper surface of the preliminary main gate electrode 131MP. At this time, a portion of the preliminary gate spacer 142P may be removed together so that the gate spacer 142 may be formed. Thereafter, the remaining portion of the preliminary gate insulating layers 132P and preliminary main gate electrodes 131MP may be removed. The upper pattern structure U_AP between the gate spacers 142 may be exposed. Subsequently, the sacrificial pattern SC_L between the channel structure CH and the lower pattern BP may be removed to form a gate trench 130t.

As shown in FIGS. 22 and 23, a sub-gate insulating layer 130S and a sub-gate electrode 120S may be sequentially formed in the gate trench 130t. In addition, the main gate insulating layer 130M, the main gate electrode 120M, and the capping layer 141 may be sequentially formed. The sub-gate insulating layer 130S and the main gate insulating layer 130M may be formed simultaneously in the same process. In this case, the sub-gate insulating layer 130S and the main gate insulating layer 130M may include the same material. The sub-gate electrode 120S and the main gate electrode 120M may be formed simultaneously in the same process. In this case, the sub-gate electrode 120S and the main gate electrode 120M may include the same material.

Subsequently, as shown in FIGS. 24 and 25, a portion of the first interlayer insulating layer 171 located between two gate structures GS facing each other in a first direction D1 may be etched through a photolithography and etching process, and a conductive material may be filled in the region where the first interlayer insulating layer 171 has been removed to form an upper contact electrode 191.

As shown in FIGS. 26 and 27, after additionally forming an interlayer insulating layer 171 on the upper surface of the capping layer 141 and the upper surface of the upper contact electrode 191, an upper contact via 193 and an upper wiring structure 410 may be formed on the first interlayer insulating layer 171. First, a contact hole may be formed by etching a portion overlapping with the upper contact electrode 191 of the additionally formed first interlayer insulating layer 171 in the third direction D3. Thereafter, a conductive material may be deposited in a contact hole formed in the second interlayer insulating layer 171 to form an upper contact via 193, and an upper wiring structure 410 may be formed on the first interlayer insulating layer 171.

As shown in FIGS. 28 and 29, the substrate 10 and the lower pattern BP may be etched. In order to remove the substrate 10 and the lower pattern BP, at least one of a grinding process, a wet etching process, a dry etching process, and a chemical mechanical polishing (CMP) process may be performed. As an example, first, by performing a chemical mechanical polishing process or a grinding process, the substrate 10 may be etched to be sufficiently thinned, and then, by performing a dry etching or wet etching process, the remaining substrate 10 and the lower pattern BP may be etched. At this time, the sub-gate insulating layer 130S may be used as an etch stop layer. In one or more embodiments, the process of etching the substrate 10 and the lower pattern BP may be performed for an appropriate time so that the lower region of the source/drain pattern 150 is not excessively damaged by the etchant.

As shown in FIGS. 30 and 31, a base insulating layer 101 may be formed in a region where the substrate 10 and the lower pattern BP are removed. In one or more embodiments, the base insulating layer 101 may include a protruding pattern PP in which the base insulating layer 101 is protruding from the upper surface. In one or more embodiments, the protruding pattern PP may be located in a region where the lower pattern BP is removed.

As shown in FIGS. 32 and 33, a portion of the base insulating layer 101 may be etched to form a recess RC. For example, a portion of the base insulating layer 101 overlapping the second source/drain pattern 152 in a third direction D3 may be etched through a photolithography and etching process. By the recess RC, a portion of the second source/drain pattern 152 may be exposed. In one or more embodiments, a portion of the lower region and the intermediate region of the second source/drain pattern 152 may be etched together with the base insulating layer 101. In one or more embodiments, a process of forming the recess RC may be performed by using an anisotropic etching process in a vertical direction for example, the third direction D3. Thereafter, an etching process in the horizontal direction (for example, the first direction D1, or the second direction D2) may additionally be performed. In this case, the width in the horizontal direction of the recess RC may be wider than that shown in FIGS. 32 and 33. In this case, as in the semiconductor device described with reference to FIG. 7 to FIG. 9, the maximum width W2 of the first contact pattern 161, see FIG. 9 in the horizontal direction may be greater than the width W1 in the horizontal direction of the upper surface of the first portion 195a.

As shown in FIGS. 34 and 35, a first contact pattern 161 may be formed covering and/or provided on at least a portion of the bottom surface and at least a portion of side surface of the recess RC. For example, the first contact pattern 161 may be formed by a selective epitaxial deposition method. In one or more embodiments, the first contact pattern 161 may include silicon germanium (SiGe). In one or more embodiments, the content of germanium (Ge) included in the first contact pattern 161 may be formed to be substantially equal to the content of germanium (Ge) included in the filling layer 152b of the second source/drain pattern 152. For example, the content of germanium (Ge) included in the first contact pattern 161 may be greater than or equal to about 42 at % and less than or equal to about 48 at %.

In one or more embodiments, after forming the first contact pattern 161, a process stabilization step may be performed before forming the second contact pattern 162. At least some of the germanium (Ge) atoms included in the first contact pattern 161 may move toward the surface during the process stabilization step. Accordingly, in a region adjacent to the lower surface, that is, the surface exposed to the outside of the first contact pattern 161, a region having a relatively large content of germanium (Ge), such as the first boundary region 161b (see FIG. 5), may be formed.

Next, as shown in FIGS. 36 and 37, a second contact pattern 162 may be formed under the first contact pattern 161 inside the recess RC. For example, the second contact pattern 162 may be formed by a selective epitaxial deposition method. In one or more embodiments, the second contact pattern 162 may include silicon germanium (SiGe) having a content of germanium (Ge) higher than that of the first contact pattern 161. For example, the content of germanium (Ge) included in the second contact pattern 162 may be greater than or equal to about 48 at % and may be less than or equal to about 54 at %.

In one or more embodiments, after the second contact pattern 162 is formed and before the third contact pattern 163 is formed, a process stabilization step may be performed. Accordingly, a region with a relatively high germanium (Ge) content, such as a second boundary region 162b (see to FIG. 5), may be formed in the exposed surface of the second contact pattern 162, that is, in the region adjacent to the lower surface.

Next, as shown in FIGS. 38 and 39, the third contact pattern 163 may be formed under the second contact pattern 162 inside the recess RC. For example, the third contact pattern 163 may be formed by a selective epitaxial deposition method. In one or more embodiments, the third contact pattern 163 may include silicon germanium (SiGe) having a content of germanium (Ge) greater than that of the second contact pattern 162. For example, the content of germanium (Ge) included in the third contact pattern 163 may be greater than or equal to about 54 at % and less than or equal to about 60 at %. In one or more embodiments, by the process stabilization step, a region with a relatively high germanium (Ge) content, such as a third boundary region 163b (see to FIG. 5), may be formed in the exposed surface of the third contact pattern 163, that is, in the region adjacent to the lower surface.

As shown in FIGS. 40 and 41, a conductive material may be deposited in the recess RC to form the lower contact electrode 195. In one or more embodiments, a silicide layer 199 may be further formed between the lower contact electrode 195 and the third contact pattern 163. As an example, the silicide layer 199 may be formed by depositing a metal material on a portion within the recess RC and then performing heat treatment at a predetermined temperature. In the example, the lower contact electrode 195 may be formed by entirely filling the recess RC with the conductive material. At this time, the conductive material may also be deposited on the lower surface of the base insulating layer 101. The conductive material deposited on the lower surface of the base insulating layer 101 may be removed by a chemical mechanical polishing process.

As shown in FIGS. 42 and 43, a lower wiring structure 420 may be formed on the lower surface of the base insulating layer 101. The lower wiring structure 420 may include lower conductive patterns 421 and a lower wiring insulating layer 422. The lower conductive patterns 421 may be positioned on the lower surface of the base insulating layer 101. The lower conductive patterns 421 may include a metal (for example, copper). The lower conductive patterns 421 may be electrically connected to the lower contact electrode 195. The lower wiring insulating layer 422 may, for example, include at least one of silicon oxide (SiO₂), silicon nitride (SiN_{X}), silicon oxynitride (SiON), or low dielectric layers.

A method of manufacturing a semiconductor device according to one or more embodiments may include forming a channel structure on a substrate, forming a gate structure surrounding the channel structure, forming source/drain patterns on opposite sides of the channel structure, removing a portion of a lower region of the source/drain patterns, forming a first contact pattern on a first portion of the removed region of the lower region, forming a second contact pattern on a second portion of the removed region below the first contact pattern, forming a lower contact electrode below the second contact pattern, and forming a lower wiring structure below the lower contact electrode, wherein the first contact pattern and the second contact pattern respectively comprise a first material having a valence band maximum higher than that of silicon, and wherein a content of the first material in the second contact pattern may be greater than a content of the first material in the first contact pattern.

In a method of manufacturing the semiconductor device according to one or more embodiments, the forming of the first contact pattern may include selectively growing silicon germanium (SiGe) on a portion of the region where the lower region of the source/drain pattern has been partially removed, using a selective epitaxial growth, and the forming of the second contact pattern may include selectively growing silicon germanium (SiGe) below the first contact pattern using a selective epitaxial growth, the silicon germanium having a higher germanium (Ge) content than that of the first contact pattern.

A method of manufacturing a semiconductor device according to one or more embodiments may further include, after forming the second contact pattern, forming a third contact pattern below the second contact pattern, wherein a content of germanium (Ge) in the third contact pattern may be greater than a content of germanium (Ge) in the second contact pattern.

A method of manufacturing a semiconductor device according to one or more embodiments may further include a step of stabilizing a process for forming the second contact pattern, after forming the first contact pattern and before forming the second contact pattern.

In a method of manufacturing a semiconductor device according to one or more embodiments, the first contact pattern and the second contact pattern may each include a main region and a boundary region positioned below the main region, and the content of germanium (Ge) in the boundary region may be greater than the content of germanium (Ge) in the main region.

According to one or more embodiments, a semiconductor device having improved electrical characteristics and enhanced reliability may be provided.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor device comprising:
a base insulating layer comprising a first surface and a second surface opposing the first surface;
a channel structure on the first surface of the base insulating layer;
a gate structure on the channel structure;
source/drain patterns connected to opposite sides of the channel structure;
a lower wiring structure on the second surface of the base insulating layer;
a lower contact electrode connecting the lower wiring structure and at least one of the source/drain patterns; and
a contact structure between the lower contact electrode and the one of the source/drain patterns, the contact structure comprising a first material having a valence band maximum higher than a valence band maximum of silicon,
wherein the contact structure comprises a first contact pattern on a lower surface of the one of the source/drain patterns, and a second contact pattern between the first contact pattern and the lower contact electrode, and
wherein a content of the first material in the second contact pattern is greater than a content of the first material in the first contact pattern.

2. The semiconductor device of claim 1, wherein the content of the first material is discontinuous at a boundary between the first contact pattern and the second contact pattern, and
wherein an average content of the first material in the second contact pattern is greater than an average content of the first material in the first contact pattern.

3. The semiconductor device of claim 1, wherein the one of the source/drain patterns, the first contact pattern, and the second contact pattern comprise silicon germanium (SiGe), and the first material comprises germanium (Ge).

4. The semiconductor device of claim 1, wherein the one of the source/drain patterns comprises the first material,
wherein an upper surface of the first contact pattern contacts a lower surface of the one of the source/drain patterns, and
wherein a content of the first material in the first contact pattern is equal to a content of the first material in at least a portion of the one of the source/drain patterns.

5. The semiconductor device of claim 1, wherein the one of the source/drain patterns comprises a liner layer along an interface with the channel structure and an interface with the gate structure, and a filling layer on an upper surface of the liner layer,
wherein a content of the first material in the filling layer is greater than a content of the first material in the liner layer, and
wherein a content of the first material in the first contact pattern is equal to a content of the first material in the filling layer.

6. The semiconductor device of claim 1, wherein the contact structure further comprises a third contact pattern between the second contact pattern and the lower contact electrode, and
wherein a content of the first material in the third contact pattern is greater than a content of the first material in the second contact pattern.

7. The semiconductor device of claim 6, wherein a content of the first material in the first contact pattern is greater than or equal to 42 at % and less than or equal to 48 at %, and
wherein a content of the first material in the second contact pattern is greater than or equal to 48 at % and less than or equal to 54 at %, and
wherein a content of the first material in the third contact pattern is greater than or equal to 54 at % and less than or equal to 60 at %.

8. The semiconductor device of claim 1, wherein the first contact pattern comprises a main region and a boundary region on the main region and the second contact pattern comprises a main region and a boundary region on the main region, and
wherein a content of the first material in the boundary region of the first contact pattern and a content of the first material in the boundary region of the second contact pattern are greater than a content of the first material in the main region of the first contact pattern and a content of the first material in the main region of the second contact pattern.

9. The semiconductor device of claim 1, wherein the one of the source/drain patterns comprises p-type dopants.

10. The semiconductor device of claim 9, wherein the first contact pattern and the second contact pattern respectively comprise the p-type dopants, and a doping concentration of the p-type dopants in the second contact pattern is greater than a doping concentration of the p-type dopants in the first contact pattern.

11. The semiconductor device of claim 1, wherein the lower contact electrode extends into the one of the source/drain patterns in a first direction perpendicular to the first surface, and
wherein the lower contact electrode comprises a first portion below the one of the source/drain patterns and a second portion on an upper surface of the first portion and overlapping the one of the source/drain patterns in a horizontal direction, and a horizontal width of the upper surface of the first portion is less than a maximum horizontal width of the contact structure.

12. The semiconductor device of claim 11, wherein the one of the source/drain patterns comprises a liner layer along an interface with the channel structure and an interface with the gate structure, and a filling layer on an upper surface of the liner layer, and
wherein at least a portion of an inner surface of the liner layer contacts an outer surface of the first contact pattern.

13. The semiconductor device of claim 12, wherein a horizontal width of the portion of the liner layer overlapping the first contact pattern is less than or equal to a horizontal width of a portion of the liner layer located at a level higher than an upper surface of the first contact pattern in a vertical direction.

14. The semiconductor device of claim 1, wherein a lower surface of the one of the source/drain patterns has a concave shape toward the upper surface of the one of the source/drain patterns, and the contact structure is included in the concave shape.

15. The semiconductor device of claim 1, further comprising a silicide layer between the contact structure and the lower contact electrode,
wherein a lower surface of the silicide layer contacts an upper surface of the lower contact electrode.

16. A semiconductor device comprising:
a base insulating layer comprising a first surface and a second surface opposing the first surface;
a channel structure on the first surface of the base insulating layer;
a gate structure on the channel structure;
source/drain patterns connected to opposite sides of the channel structure and comprising silicon germanium (SiGe);
a lower wiring structure on the second surface of the base insulating layer;
a lower contact electrode connecting the lower wiring structure and at least one of the source/drain patterns; and
a contact structure between the lower contact electrode and the one of the source/drain patterns, the contact structure comprising silicon germanium (SiGe),
wherein the contact structure comprises a first contact pattern on a lower surface of the one of the source/drain patterns and a second contact pattern located between the first contact pattern and the lower contact electrode,
wherein the first contact pattern and the second contact pattern respectively comprise a main region and a boundary region below the main region, and
wherein a content of germanium (Ge) in the boundary region of the first contact pattern and a content of germanium (Ge) in the boundary region of the second contact pattern are greater than a content of germanium (Ge) in the main region of the first contact pattern and a content of germanium (Ge) in the main region of the second contact pattern.

17. The semiconductor device of claim 16, wherein a content of germanium (Ge) in the second contact pattern is greater than a content of germanium (Ge) in the first contact pattern.

18. The semiconductor device of claim 16, wherein a content of germanium (Ge) in the boundary region of the first contact pattern is greater than or equal to a content of germanium (Ge) in the main region of the second contact pattern.

19. The semiconductor device of claim 16, wherein a content of germanium (Ge) is discontinuous at a boundary between the first contact pattern and the second contact pattern, and
wherein an average content of germanium (Ge) in the second contact pattern is greater than an average content of germanium (Ge) in the first contact pattern.

20. A semiconductor device comprising:
a base insulating layer comprising a first surface and a second surface opposing the first surface;
a channel structure on the first surface of the base insulating layer;
a gate structure on the channel structure;
a first source/drain pattern and a second source/drain pattern connected to opposite sides of the channel structure and comprising silicon germanium (SiGe);
an upper wiring structure on the first source/drain pattern and the second source/drain pattern;
an upper contact electrode in contact with an upper surface of the first source/drain pattern and connecting the upper wiring structure and the first source/drain pattern;
a lower wiring structure on the second surface of the base insulating layer;
a lower contact electrode connecting the lower wiring structure and the second source/drain pattern;
a first contact pattern on a lower surface of the second source/drain pattern, an upper surface of the first contact pattern contacting the lower surface of the second source/drain pattern;
a second contact pattern below the first contact pattern;
a third contact pattern located between the second contact pattern and the lower contact electrode, a lower surface of the third contact pattern contacting an upper surface of the lower contact electrode,
wherein the first contact pattern, the second contact pattern, and the third contact pattern each comprise silicon germanium (SiGe),
wherein the first contact pattern, the second contact pattern, and the third contact pattern each comprise a main region and a boundary region below the main region, and
wherein a content of germanium (Ge) in the third contact pattern is greater than a content of germanium (Ge) in the second contact pattern, and a content of germanium (Ge) in the second contact pattern is greater than a content of germanium (Ge) in the first contact pattern.
